(19) United States
(12) Patent Application Publication
(10) Pub. No.: US 2025/0126844 A1
(43) Pub. Date: Apr. 17, 2025

(54) TRANSISTOR AND MANUFACTURING METHOD FOR TRANSISTOR

(71) Applicant: Sharp Display Technnology Corporation, Kameyama City (JP)

(72) Inventors: Tadayoshi MIYAMOTO, Kameyama City (JP); Yoshinobu NAKAMURA, Kameyama City (JP); Toshihiro KANEKO, Kameyama City (JP); Sohtaroh TANAKA, Kameyama City (JP)

(21) Appl. No.: 18/900,603

(22) Filed: Sep. 27, 2024

(30) Foreign Application Priority Data
Oct. 17, 2023 (JP) 2023-178700

(51) Int. Cl. H01L 29/786; G02F 1/1368; H01L 29/66

(52) U.S. Cl. CPC H10D 30/6755; G02F 1/1368; H10D 30/0321; H10D 30/6745

(57) ABSTRACT

A gate insulating film includes a first thick portion and a second thick portion having the same film thickness, and a third thick portion, a fourth thick portion, and a fifth thick portion all having a film thickness larger than a thickness of the first thick portion, the first thick portion and the second thick portion overlap both the first electrode and a semiconductor portion and are disposed at positions spaced apart from each other in a first direction, the third thick portion is interposed between the first thick portion and the second thick portion, and the fourth thick portion and the fifth thick portion are disposed to overlap both the semiconductor portion and both end portions of a first electrode.

### CROSS-REFERENCE TO RELATED APPLICATIONS

This application claims the benefit of priority to Japanese Patent Application Number 2023-178700 filed on Oct. 17, 2023. The entire contents of the above-identified application are hereby incorporated by reference.

### BACKGROUND

### Technical Field

The technology described in the present specification relates to a transistor and a manufacturing method for the transistor.

In the related art, an example of a transistor is known, as described in JP 2010-266490 A. JP 2010-266490 A discloses a transistor having a single-gate structure and a transistor having a multi-gate structure in which two or more transistors are connected in series.

### SUMMARY

In the transistor having a single-gate structure disclosed in JP 2010-266490 A, hot carrier injection is likely to occur when a high voltage is applied, thereby resulting in a concern that transistor performance may deteriorate over time. In addition, electro-static discharge (ESD) is likely to occur between an end portion of a gate metal and a channel material, and the end portion of the gate metal and the channel material are damaged due to the ESD, resulting in a concern that a yield may be deteriorated.

In the transistor having a multi-gate structure disclosed in JP 2010-266490 A, hot carrier injection is less likely to occur even when a high voltage is applied. However, since the number of end portions of a gate metal is larger than that of the single-gate structure, ESD is more likely to occur between the end portion of the gate metal and a channel material. For this reason, the end portion of the gate metal or the channel material may be damaged due to the ESD, resulting in a concern that a yield may be lowered.

The technology described in this specification has been contrived in view of the above circumstances, and an object thereof is to improve a yield.

(1) A transistor according to the technology described in this specification includes a semiconductor portion extending in a first direction and made of a semiconductor material, a first electrode disposed overlapping a portion of the semiconductor portion, a first insulating film interposed between the first electrode and the semiconductor portion, a second electrode disposed overlapping a portion of the semiconductor portion and connected to the semiconductor portion, and a third electrode disposed overlapping a portion of the semiconductor portion at a position spaced apart from a connection position between the second electrode and the semiconductor portion in the first direction and connected to the semiconductor portion, in which the first insulating film includes a first thick portion, a second thick portion having the same film thickness as a thickness of the first thick portion, a third thick portion having a film thickness larger than the thickness of the first thick portion, a fourth thick portion having a film thickness larger than the thickness of the first thick portion, and a fifth thick portion having a film thickness larger than the thickness of the first thick portion, the first thick portion is disposed at a position overlapping both the first electrode and the semiconductor portion, the second thick portion overlaps both the first electrode and the semiconductor portion and is disposed at a position spaced apart from the first thick portion in the first direction, the third thick portion overlaps both the first electrode and the semiconductor portion and is disposed to be interposed between the first thick portion and the second thick portion in the first direction, the fourth thick portion is disposed overlapping both the semiconductor portion and one end portion of the first electrode in the first direction, and the fifth thick portion is disposed overlapping both the semiconductor portion and the other end portion of the first electrode in the first direction.

(2) In addition to (1) described above, in the transistor, the first insulating film may have a layered structure of a lower insulating film disposed on an upper layer side of the semiconductor portion and an upper insulating film disposed on an upper layer side of the lower insulating film and made of a material different from a material of the lower insulating film.

(3) In addition to (1) described above, in the transistor, the first insulating film may have a single-layer structure.

(4) In addition to any one of (1) to (3) described above, in the transistor, the third thick portion, the fourth thick portion, and the fifth thick portion may have the same film thickness.

(5) In addition to any one of (1) to (4) described above, in the transistor, the first thick portion and the second thick portion may have the same dimension in the first direction.

(6) In addition to any one of (1) to (4) described above, in the transistor, the second electrode may be connected to a signal supply source and receive a signal supplied from the signal supply source, whereas the third electrode is connected to a signal supply target and is configured to supply the signal to the signal supply target, the first thick portion may be located closer to the second electrode in the first direction than the third thick portion, and the second thick portion may be located closer to the third electrode in the first direction than the third thick portion, and have a larger dimension in the first direction than the first thick portion.

(7) In addition to any one of (1) to (6) described above, in the transistor, a polysilicon semiconductor material may be used as the semiconductor material for the semiconductor portion.

(8) In addition to any one of (1) to (6) described above, in the transistor, an oxide semiconductor material may be used as the semiconductor material for the semiconductor portion.

(9) A transistor according to the technology described in this specification includes a semiconductor portion extending in a first direction and made of a semiconductor material, a first electrode disposed overlapping a portion of the semiconductor portion, a fourth electrode overlapping a portion of the semiconductor portion and disposed at a position spaced apart from the first electrode in the first direction, a first insulating film interposed between the first and fourth electrodes and the semiconductor portion, a second electrode disposed overlapping a portion of the semiconductor portion and connected to the semiconductor portion, and a third electrode disposed overlapping a portion of the semiconductor portion at a position spaced apart from a connection position between the second electrode and the semiconductor portion in the first direction and connected to the semiconductor portion, in which the first insulating film includes a first thick portion, a second thick portion having the same film thickness as a thickness of the first thick portion, a third thick portion having a film thickness larger than the thickness of the first thick portion, a fourth thick portion having a film thickness larger than the thickness of the first thick portion, and a fifth thick portion having a film thickness larger than the thickness of the first thick portion, the first thick portion is disposed at a position overlapping both the first electrode and the semiconductor portion, the second thick portion is disposed at a position overlapping both the fourth electrode and the semiconductor portion, the third thick portion is disposed to be interposed between the first thick portion and the second thick portion in the first direction, the fourth thick portion overlaps both one end portion of the first electrode in the first direction and the semiconductor portion, and is disposed to sandwich the first thick portion with the third thick portion, the fifth thick portion overlaps both one end portion of the fourth electrode in the first direction and the semiconductor portion, and is disposed to sandwich the second thick portion with the third thick portion, and the third thick portion is disposed overlapping both the semiconductor portion and the other end portion of the first electrode in the first direction and overlap both the semiconductor portion and the other end portion of the fourth electrode in the first direction.

(10) A manufacturing method for a transistor according to the technology described in this specification includes forming a semiconductor film made of a semiconductor material and patterning the semiconductor film to provide a semiconductor portion extending in a first direction, forming a first insulating film on an upper layer side of the semiconductor portion, forming a first resist film made of a photosensitive material on an upper layer side of the first insulating film, exposing and developing the first resist film, etching the first insulating film using the first resist film as a mask to provide a first thick portion overlapping the semiconductor portion, a second thick portion overlapping the semiconductor portion, disposed at a position spaced apart from the first thick portion in the first direction, and having the same film thickness as a thickness of the first thick portion, a third thick portion disposed to be interposed between the first thick portion and the second thick portion in the first direction at a position overlapping the semiconductor portion, a fourth thick portion overlapping the semiconductor portion, disposed to sandwich the first thick portion with the third thick portion in the first direction, and having a film thickness larger than the thickness of the first thick portion, and a fifth thick portion overlapping the semiconductor portion, disposed to sandwich the second thick portion with the third thick portion in the first direction, and having a film thickness larger than the thickness of the first thick portion, forming a first conductive film on an upper layer side of the first insulating film, forming a second resist film made of a photosensitive material on an upper layer side of the first conductive film, exposing and developing the second resist film, etching the first conductive film using the second resist film as a mask to provide a first electrode in which one end portion in the first direction overlaps the fourth thick portion, the other end portion in the first direction overlaps the fifth thick portion, and a portion between both end portions in the first direction overlaps the first thick portion, the second thick portion, and the third thick portion, and forming a second conductive film on an upper layer side of the first electrode and patterning the second conductive film to provide a second electrode that is disposed overlapping a portion of the semiconductor portion and is connected to the semiconductor portion, and a third electrode that is disposed overlapping a portion of the semiconductor portion at a position spaced apart from a connection position between the second electrode and the semiconductor portion in the first direction and is connected to the semiconductor portion.

(11) In addition to (10) described above, the manufacturing method for the transistor may further include forming the first resist film made of a positive type photosensitive material on the upper layer side of the first insulating film, exposing the first resist film through a first photomask and then developing the first resist film, the first photomask including a first light shielding region that is disposed overlapping formation areas for the fourth thick portion and the fifth thick portion to be formed to block light, a first transmissive region that overlaps formation areas for the first thick portion and the second thick portion to be formed to block light, and a semi-transmissive region that overlaps a formation areas for the third thick portion to be formed, is disposed to be interposed between two of the first transmissive regions in the first direction, and has a light transmittance higher than a light transmittance of the first light shielding region and lower than a light transmittance of the first transmissive region, forming the second resist film made of a negative photosensitive material on the upper layer side of the first conductive film, and exposing the second resist film through the first photomask and then developing the second resist film.

(12) A manufacturing method for a transistor according to the technology described in this specification includes forming a semiconductor film made of a semiconductor material and patterning the semiconductor film to provide a semiconductor portion extending in a first direction, forming a first insulating film on an upper layer side of the semiconductor portion, forming a first resist film made of a photosensitive material on an upper layer side of the first insulating film, exposing and developing the first resist film, etching the first insulating film using the first resist film as a mask to provide a first thick portion overlapping the semiconductor portion, a second thick portion overlapping the semiconductor portion, disposed at a position spaced apart from the first thick portion in the first direction, and having the same film thickness as a thickness of the first thick portion, a third thick portion disposed to be interposed between the first thick portion and the second thick portion in the first direction at a position overlapping the semiconductor portion, a fourth thick portion overlapping the semiconductor portion, disposed to sandwich the first thick portion with the third thick portion in the first direction, and having a film thickness larger than the thickness of the first thick portion, and a fifth thick portion overlapping the semiconductor portion, disposed to sandwich the second thick portion with the third thick portion in the first direction, and having a film thickness larger than the thickness of the first thick portion, forming a first conductive film on an upper layer side of the first insulating film, forming a second resist film made of a photosensitive material on an upper layer side of the first conductive film, exposing and developing the second resist film, etching the first conductive film using the second resist film as a mask to provide a first electrode in which one end portion in the first direction overlaps the fourth thick portion, the other end portion in the first direction overlaps the third thick portion, and a portion between both end portions in the first direction overlaps the first thick portion, and a fourth electrode in which one end portion in the first direction overlaps the fifth thick portion, the other end portion in the first direction overlaps the third thick portion, and a portion between both end portions in the first direction overlaps the second thick portion, and forming a second conductive film on an upper layer side of the first electrode and patterning the second conductive film to provide a second electrode that is disposed overlapping a portion of the semiconductor portion and is connected to the semiconductor portion, and a third electrode that is disposed overlapping a portion of the semiconductor portion at a position spaced apart from a connection position between the second electrode and the semiconductor portion in the first direction and is connected to the semiconductor portion.

(13) In addition to (12) described above, the manufacturing method for the transistor may further include forming the first resist film made of a positive type photosensitive material on the upper layer side of the first insulating film, exposing the first resist film through a second photomask and then developing the first resist film, the second photomask including a second light shielding region that is disposed overlapping formation areas for the third thick portion, the fourth thick portion, and the fifth thick portion to be formed to block light, and a second transmissive region that overlaps formation areas for the first thick portion and the second thick portion to be formed to block light, forming the second resist film made of a negative photosensitive material on the upper layer side of the first conductive film, and exposing the second resist film through the second photomask and then developing the second resist film.

According to the technology described in this specification, it is possible to improve a yield.

### BRIEF DESCRIPTION OF DRAWINGS

The disclosure will be described with reference to the accompanying drawings, wherein like numbers reference like elements.

FIG. 1 is a plan view of a liquid crystal panel, a driver, a flexible substrate, and the like which constitute a liquid crystal display device according to a first embodiment.

FIG. 2 is a cross-sectional view of the liquid crystal panel, the driver, the flexible substrate, and the like according to the first embodiment.

FIG. 3 is a circuit diagram showing an electrical configuration of an array substrate that constitutes the liquid crystal panel according to the first embodiment.

FIG. 4 is a cross-sectional view of a first TFT and a second TFT provided on the array substrate according to the first embodiment.

FIG. 5 is a plan view of the first TFT according to the first embodiment.

FIG. 6 is a cross-sectional view of the first TFT according to the first embodiment, which is taken along a line vi-vi in FIG. 5.

FIG. 7 is a cross-sectional view of the first TFT according to the first embodiment, which is taken along a line vii-vii in FIG. 5.

FIG. 8 is a cross-sectional view similar to FIG. 6, showing a state where a lower insulating film, an upper insulating film, and a first resist film are formed in a fourth step included in an array substrate manufacturing step according to the first embodiment.

FIG. 9 is a cross-sectional view similar to FIG. 6, showing a state where the first resist film is exposed through a first photomask in the fourth step included in the array substrate manufacturing step according to the first embodiment.

FIG. 10 is a cross-sectional view similar to FIG. 6, showing a state where the first resist film is developed in the fourth step included in the array substrate manufacturing step according to the first embodiment.

FIG. 11 is a cross-sectional view similar to FIG. 6, showing a state where the upper insulating film is etched through the first resist film in the fourth step included in the array substrate manufacturing step according to the first embodiment.

FIG. 12 is a cross-sectional view similar to FIG. 6, showing a state where the first resist film is removed in the fourth step included in the array substrate manufacturing step according to the first embodiment.

FIG. 13 is a cross-sectional view similar to FIG. 6, showing a state where a second metal film and a second resist film are formed in a fifth step included in the array substrate manufacturing step according to the first embodiment.

FIG. 14 is a cross-sectional view similar to FIG. 6, showing a state where the second resist film is exposed through the first photomask in the fifth step included in the array substrate manufacturing step according to the first embodiment.

FIG. 15 is a cross-sectional view similar to FIG. 6, showing a state where the second resist film is developed in the fifth step included in the array substrate manufacturing step according to the first embodiment.

FIG. 16 is a cross-sectional view similar to FIG. 6, showing a state where the second metal film is etched through the second resist film in the fifth step included in the array substrate manufacturing step according to the first embodiment.

FIG. 17 is a cross-sectional view similar to FIG. 6, showing a first TFT according to a second embodiment.

FIG. 18 is a cross-sectional view similar to FIG. 6, showing a first TFT according to a third embodiment.

FIG. 19 is a cross-sectional view of a first TFT and a second TFT provided in an array substrate according to a fourth embodiment.

FIG. 20 is a plan view of the first TFT according to the fourth embodiment.

FIG. 21 is a cross-sectional view of the first TFT according to the fourth embodiment, which is taken along a line xxi-xxi in FIG. 20.

FIG. 22 is a cross-sectional view of the first TFT according to the fourth embodiment, which is taken along a line xxii-xxii in FIG. 20.

FIG. 23 is a cross-sectional view similar to FIG. 21, showing a state where a lower insulating film, an upper insulating film, and a first resist film are formed in a fourth step included in an array substrate manufacturing step according to the fourth embodiment.

FIG. 24 is a cross-sectional view similar to FIG. 21, showing a state where the first resist film is exposed through a second photomask in the fourth step included in the array substrate manufacturing step according to the fourth embodiment.

FIG. 25 is a cross-sectional view similar to FIG. 21, showing a state where the first resist film is developed in the fourth step included in the array substrate manufacturing step according to the fourth embodiment.

FIG. 26 is a cross-sectional view similar to FIG. 21, showing a state where the upper insulating film is etched through the first resist film in the fourth step included in the array substrate manufacturing step according to the fourth embodiment.

FIG. 27 is a cross-sectional view similar to FIG. 21, showing a state where the first resist film is removed in the fourth step included in the array substrate manufacturing step according to the fourth embodiment.

FIG. 28 is a cross-sectional view similar to FIG. 21, showing a state where a second metal film and a second resist film are formed in a fifth step included in the array substrate manufacturing step according to the fourth embodiment.

FIG. 29 is a cross-sectional view similar to FIG. 21, showing a state where the second resist film is exposed through the second photomask in the fifth step included in the array substrate manufacturing step according to the fourth embodiment.

FIG. 30 is a cross-sectional view similar to FIG. 21, showing a state where the second resist film is developed in the fifth step included in the array substrate manufacturing step according to the fourth embodiment.

FIG. 31 is a cross-sectional view similar to FIG. 21, showing a state where a second metal film is etched through the second resist film in the fifth step included in the array substrate manufacturing step according to the fourth embodiment.

FIG. 32 is a cross-sectional view similar to FIG. 6, showing a first TFT according to a fifth embodiment.

### DESCRIPTION OF EMBODIMENTS

### First Embodiment

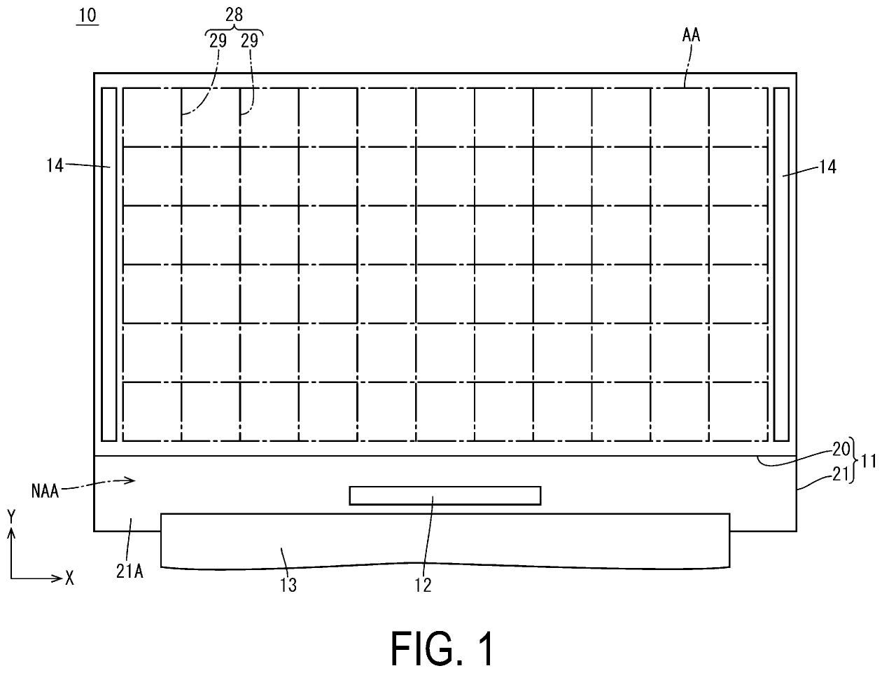

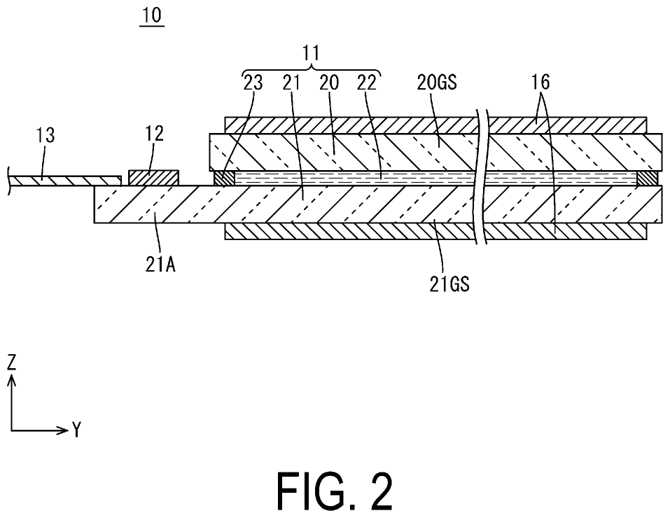

A first embodiment will be described with reference to FIG. 1 to FIG. 17. In this embodiment, a liquid crystal display device 10 having a display function and a touch panel function (position input function) will be described. Some drawings show an X-axis, a Y-axis, and a Z-axis, and axial directions are drawn to be directions shown in the drawings. In addition, an upper side and a lower side in each of FIGS. 2, 4, and 6 to 17 are respectively defined as a front side and a rear side.

The liquid crystal display device 10, as shown in FIG. 1, includes at least the liquid crystal panel (display device, display panel) 11 that has a horizontally elongated rectangular shape and is capable of displaying an image, and a backlight device (illumination device), which is an external light source configured to irradiate the liquid crystal panel 11 with light to be used for display. The backlight device includes a light source (for example, an LED or the like) disposed on the back side (back face side) of the liquid crystal panel 11 and configured to emit light of a white color (white light), an optical member configured to impart an optical effect on the light from the light source, thereby converting the light into planar light, and the like. A center-side portion of a screen of the liquid crystal panel 11 is a display region AA in which an image is displayed. On the other hand, a frame-shaped outer peripheral portion surrounding the display region AA in the screen of the liquid crystal panel 11 is a non-display region NAA in which images are not displayed.

As shown in FIG. 1, a circuit portion (peripheral circuit portion) 14 is provided in the non-display region NAA of the liquid crystal panel 11. A pair of circuit portions 14 are disposed to sandwich the display region AA from both sides thereof in the X-axis direction. The circuit portions 14 are provided in a belt-shaped range extending in the Y-axis direction. The circuit portions 14 are configured to supply a scanning signal to a gate wiring line 26 to be described later, and are monolithically provided on an array substrate 21 to be described later. The circuit portion 14 is a gate driver monolithic (GDM) circuit. The circuit portion 14 includes a shift register circuit configured to output a scanning signal at a predetermined timing, a buffer circuit for amplifying the scanning signal, and the like. The circuit portion 14 is provided with various circuit elements including at least a first transistor (TFT) 15. A detailed configuration of the first TFT 15 will be described later.

The liquid crystal panel 11 will be described in detail with reference to FIG. 2 in addition to FIG. 1. As shown in FIGS. 1 and 2, the liquid crystal panel 11 is formed by bonding a pair of substrates 20 and 21 together. Out of the pair of substrates 20 and 21, the front side (front face side) is a counter substrate (CF substrate, second substrate) 20, and the back side (back face side) is an array substrate (first substrate) 21. Both the counter substrate 20 and the array substrate 21 are formed by layering various films on inner face sides of glass substrates 20GS and 21GS. A liquid crystal layer (medium layer) 22 containing liquid crystal molecules, which are substances having optical characteristics that change in accordance with application of an electrical field, is interposed between the pair of substrates 20 and 21. A sealing portion 23 that seals the liquid crystal layer 22 is provided to be interposed between outer peripheral ends of the pair of substrates 20 and 21. The sealing portion 23 is formed in a rectangular frame shape (endless ring shape) to surround the liquid crystal layer 22. Polarizers 16 are bonded to the outer face sides of both the substrates 20 and 21, respectively.

As shown in FIG. 1 and FIG. 2, the counter substrate 20 has a short side dimension shorter than a short side dimension of the array substrate 21. The counter substrate 20 is bonded to the array substrate 21 with one end in a short side direction (Y-axis direction) aligned with the array substrate 21. Thus, the other end of the array substrate 21 in the short side direction is an exposed portion 21A that protrudes laterally relative to the counter substrate 20 and is exposed. The exposed portion 21A is entirely a non-display region NAA, and is equipped with a driver (mounted component, signal supply unit) 12 and a flexible substrate 13 for supplying various signals related to a display function and a touch panel function to be described below.

The driver 12 shown in FIGS. 1 and 2 is constituted of an LSI chip having an internal drive circuit. The driver 12 is mounted on the exposed portion 21A of the array substrate 21 in a chip-on-glass (COG) manner. The driver 12 processes various signals transmitted by the flexible substrate 13. The driver 12 supplies various signals (for example, image signals, touch signals, and the like) to wiring lines in the display region AA (specifically, source wiring lines 27 and touch wiring lines 30, which will be described later). The flexible substrate 13 has a configuration in which a large number of wiring line patterns are formed on a base material made of a synthetic resin material (for example, a polyimide resin or the like) having insulating properties and flexibility. As shown in FIG. 1 and FIG. 2, one end side of the flexible substrate 13 is connected to the exposed portion 21A of the array substrate 21, and the other end side thereof is connected to an external circuit substrate (control substrate, or the like). The flexible substrate 13 is connected to an end of the exposed portion 21A on a side opposite to the display region AA side in the Y-axis direction with respect to the driver 12.

The liquid crystal panel 11 according to this embodiment has both a display function of displaying an image and a touch panel function of detecting a position (input position) input by a user based on the displayed image. In the liquid crystal panel 11, a touch panel pattern for exhibiting the touch panel function is integrated (in an in-cell form). The touch panel pattern is a so-called projected electrostatic capacitive type, and the detection type thereof is a self-capacitance type. As shown in FIG. 1, the touch panel pattern is constituted of a plurality of touch electrodes (position detection electrodes) 29 disposed lined up in a matrix on a plate surface of the liquid crystal panel 11. A touch electrode 29 is disposed in the display region AA of the liquid crystal panel 11. Thus, the display region AA of the liquid crystal panel 11 substantially matches a touch region (position input region) in which an input position can be detected, and the non-display region NAA substantially matches a non-touch region (non-position input region) in which an input position cannot be detected. When a user brings his or her finger (position input object), which is a conductor, close to the surface (display surface) of the liquid crystal panel 11 to input a position based on the image of the display region AA of the liquid crystal panel 11 that is visually recognized, electrostatic capacitance is formed between the finger and the touch electrode 29. Thereby, the electrostatic capacitance detected by the touch electrode 29 near the finger changes as the finger approaches, and is different from that of the touch electrode 29 farther away from the finger, making it possible to detect an input position based on this. A specific number of touch electrodes 29 installed can be changed appropriately, in addition to the touch electrodes 29 shown in FIG. 1. The touch electrode 29 has a substantially rectangular shape in a plan view, and the dimension of one side of the touch electrode 29 is approximately several mm. Thus, the size of the touch electrode 29 in a plan view is much larger than a pixel to be described later, and is disposed in a range that spans a plurality of pixels in the X-axis direction and the Y-axis direction.

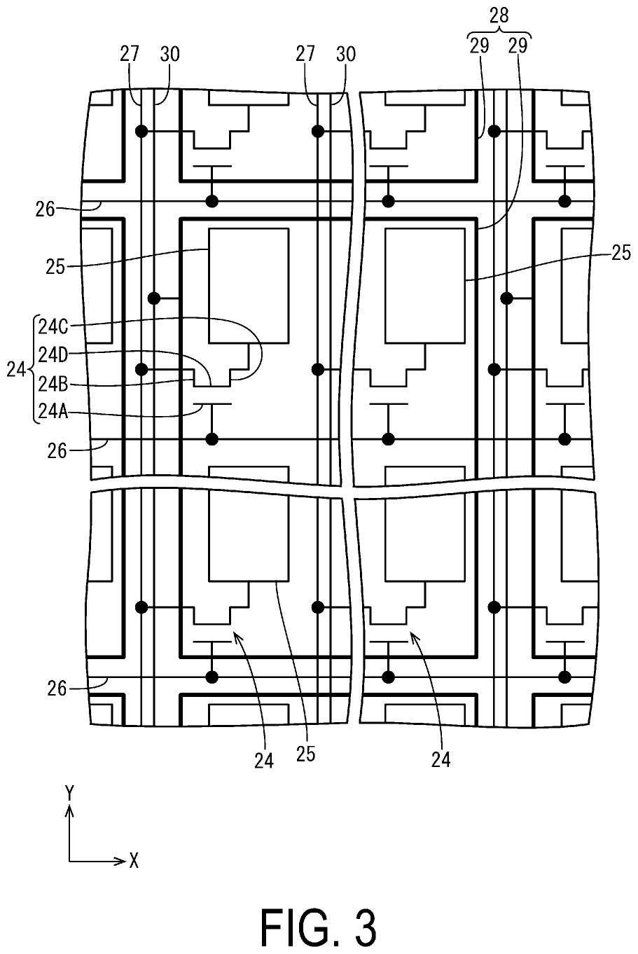

Next, a configuration of the display region AA in the array substrate 21 will be described with reference to FIG. 3. As shown in FIG. 3, at least a second TFT (second transistor) 24 and a pixel electrode 25 are provided on the inner surface of the array substrate 21 in the display region AA. A plurality of the second TFTs 24 and a plurality of the pixel electrodes 25 are provided lined up in a matrix at intervals in the X-axis direction and the Y-axis direction. Gate wiring lines (scanning wiring lines) 26 and source wiring lines (image wiring lines, signal wiring lines) 27 that are orthogonal to (intersecting) each other are disposed around the second TFTs 24 and the pixel electrodes 25. The gate wiring lines 26 extend in the X-axis direction. The source wiring lines 27 extend in the Y-axis direction. The second TFT 24 includes a second gate electrode 24A connected to the gate wiring line 26, a second source electrode 24B connected to the source wiring line 27, a second drain electrode 24C connected to the pixel electrode 25, and a second semiconductor portion 24D connected to the second source electrode 24B and the second drain electrode 24C. The second TFT 24 is driven based on a scanning signal supplied to the second gate electrode 24A by the gate wiring line 26. Then, a potential related to an image signal (data signal) supplied from the driver 12 to the second source electrode 24B through the source wiring line 27 is supplied to the second drain electrode 24C through the second semiconductor portion 24D. As a result, the pixel electrode 25 is charged to the potential related to the image signal. The pixel electrode 25 is disposed in a region surrounded by the gate wiring line 26 and the source wiring line 27, and has a planar shape of, for example, a substantially rectangular shape.

As shown in FIG. 3, a common electrode 28 is formed on the inner surface side of the array substrate 21 in the display region AA so as to overlap all of the pixel electrodes 25. The common electrode 28 extends over substantially the entire display region AA. The common electrode 28 constitutes the touch electrode 29 that has already been described. The common electrode 28 has partition slits that separate adjacent touch electrodes 29. The common electrode 28 is divided into a grid pattern by the partition slits, and is constituted of the plurality of touch electrodes 29 which are electrically independent of each other.

As shown in FIG. 3, a plurality of touch wiring lines (wiring lines, position detection wiring lines) 30 connected to the plurality of touch electrodes 29 are provided on the inner surface side of the array substrate 21 in the display region AA. The touch wiring lines 30 extend in the Y-axis direction and are parallel to the source wiring lines 27. The plurality of touch wiring lines 30 are individually connected to the plurality of touch electrodes 29. A common signal (reference potential signal) related to the display function and a touch signal (position detection signal) related to the touch function are supplied to the touch wiring lines 30 from the driver 12 at different timings (on a time-division basis). The timing when the common signal is supplied from the driver 12 to the touch wiring lines 30 is a display period, and the timing when the touch signal is supplied from the driver 12 to the touch wiring lines 30 is a sensing period (position detection period). During the display period, the common signal is supplied to all of the touch wiring lines 30, and thus all of the touch electrodes 29 are set to a reference potential and function as the common electrodes 28.

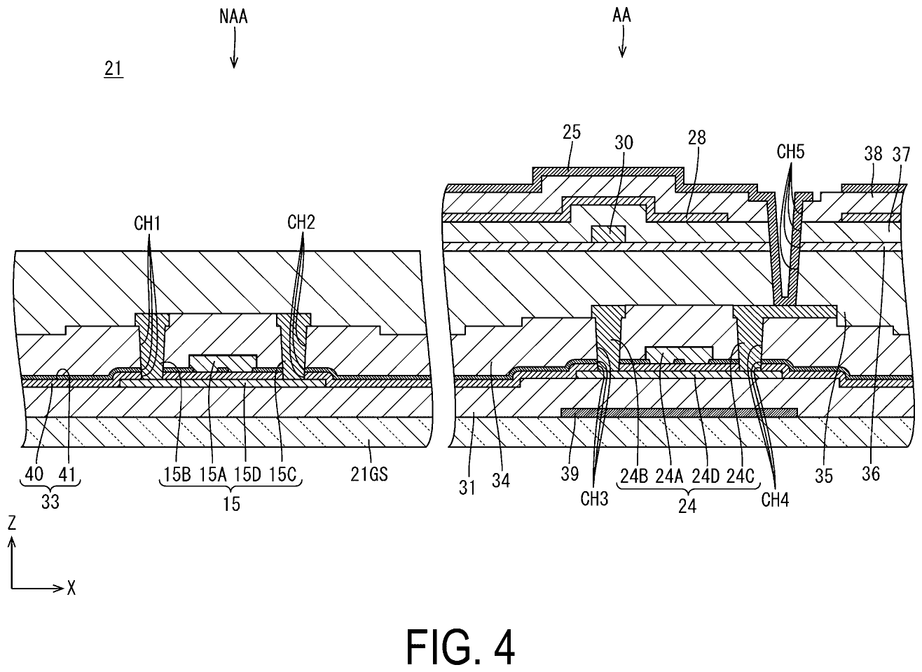

Next, various films layered on the glass substrate (substrate) 21GS of the array substrate 21 will be described in detail with reference to FIG. 4. FIG. 4 shows a cross-sectional configuration of the circuit portion 14 (first TFT 15) in the non-display region NAA and a cross-sectional configuration in the display region AA (second TFT 24). As shown in FIG. 4, at least a first metal film (light shielding film), a base coat film 31, a semiconductor film, a gate insulating film (first insulating film) 33, a second metal film (first conductive film) 32 (see FIG. 13), a first interlayer insulating film (second insulating film) 34, a third metal film (second conductive film), a flattening film 35, a second interlayer insulating film 36, a fourth metal film (third conductive film), a third interlayer insulating film 37, a first transparent electrode film, a fourth interlayer insulating film 38, a second transparent electrode film, and an alignment film are formed to be layered on the glass substrate 21GS of the array substrate 21 in this order from the lower layer side (glass substrate 21GS side).

The first metal film, the second metal film 32, the third metal film and the fourth metal film are each configured as a single layer film made of one type of metal material or configured as a layered film or an alloy made of different types of metal materials, and thus have conductivity and light shielding properties.

Specifically, the first metal film is a single layer film made of, for example, Mo (molybdenum) and has a film thickness of, for example, approximately 50 nm. The second metal film 32 is a single layer film made of, for example, Mo (molybdenum) and has a film thickness of, for example, approximately 300 nm. The second metal film 32 is a layered film including, for example, Ti (titanium)/Al (aluminum)/Ti in this order from the upper layer side, and has a film thickness of, for example, approximately 50 nm/approximately 350 nm/approximately 100 nm. The third metal film is a layered film including, for example, Mo/Al/Mo in this order from the upper layer side, and has a film thickness of, for example, approximately 100 nm/approximately 300 nm/approximately 30 nm. The semiconductor film is made of a polysilicon semiconductor material (semiconductor material) having a crystalline substance created by a known method such as laser crystallization, and the polysilicon semiconductor material of the semiconductor film, which has a film thickness of, for example, approximately 50 nm, has a higher electron mobility than that of an amorphous silicon semiconductor material or an oxide semiconductor material. The first transparent electrode film and the second transparent electrode film are made of a transparent electrode material such as ITO (indium tin oxide), and each has a film thickness of, for example, approximately 60 nm.

The base coat film 31, the gate insulating film 33, the first interlayer insulating film 34, the second interlayer insulating film 36, the third interlayer insulating film 37 and the fourth interlayer insulating film 38 are all made of SiO₂ (silicon oxide) or SiNₓ (silicon nitride) which is a type of an inorganic material (inorganic resin material). Specifically, the base coat film 31 is a layered film made of SiO₂/SiNₓ in this order from the upper layer side and has a film thickness of, for example, approximately 200 nm/approximately 100 nm. The gate insulating film 33 is a layered film made of SiN/SiO₂ in this order from the upper layer side and has a film thickness of, for example, approximately 50 nm/approximately 100 nm. The first interlayer insulating film 34 is a layered film made of SiNₓ/SiO₂ in this order from the upper layer side and has a film thickness of, for example, approximately 300 nm/approximately 300 nm. The second interlayer insulating film 36 is a single layer film of SiNₓ and has a film thickness of, for example, approximately 100 nm. The third interlayer insulating film 37 is a single layer film of SiNₓ and has a film thickness of, for example, approximately 100 nm. The fourth interlayer insulating film 38 is a single layer film of SiNₓ and has a film thickness of, for example, approximately 200 nm. The flattening film 35 is made of PMMA (acrylic resin), which is a type of organic material (organic resin material), and has a film thickness in the range of, for example, approximately 1 μm to 3 μm. In other words, the flattening film 35 has a film thickness greater than those of the other insulating films 31, 33, 34, 36, 37, and 38 that are made of inorganic materials.

Next, a cross-sectional configuration of the circuit portion 14 will be described in detail. As shown in FIG. 4, the circuit portion 14 includes the first TFT 15. The first TFT 15 includes a first gate electrode (first electrode) 15A, a first source electrode (second electrode) 15B, a first drain electrode (third electrode) 15C, and a first semiconductor portion (semiconductor portion) 15D. Among these, the first semiconductor portion 15D is located on the lowermost layer side with respect to the electrodes 15A to 15C, and is constituted by the semiconductor film. Thus, the first TFT 15 can be said to be a so-called top-gate type transistor.

As shown in FIG. 4, the first gate electrode 15A is constituted by the second metal film 32. The first gate electrode 15A is disposed to overlap the upper layer side of the first semiconductor portion 15D via the gate insulating film 33. The first gate electrode 15A is disposed to overlap the center-side portion of the first semiconductor portion 15D in the X-axis direction (first direction).

As shown in FIG. 4, the first source electrode 15B and the first drain electrode 15C are both constituted of a third metal film. The first source electrode 15B is connected to a signal supply source (for example, the driver 12, the flexible substrate 13, or the like) and receives a signal supplied from the signal supply source. The first drain electrode 15C is connected to a signal supply target (for example, the gate wiring line 26 or the like) and can supply a signal (scanning signal) to the signal supply target. When a voltage equal to or higher than a threshold voltage in the first TFT 15 is applied to a first gate electrode 215A, a signal supplied from the signal supply source to the first source electrode 15B is transmitted to the first drain electrode 15C via the channel region 215D1 formed in the first semiconductor portion 215D and is supplied from the first drain electrode 15C to the signal supply target. The first source electrode 15B and the first drain electrode 15C are disposed to overlap a portion of the first semiconductor portion 15D on the upper layer side via the gate insulating film 33 and the first interlayer insulating film 34. The first source electrode 15B is disposed to overlap one end-side portion (the left side in FIG. 4) of the first semiconductor portion 15D in the X-axis direction. The first source electrode 15B and the first semiconductor portion 15D are connected to each other through a first contact hole CH1 that is opened to communicate with the gate insulating film 33 and the first interlayer insulating film 34 interposed therebetween. In other words, the first contact hole CH1 is at a connection position between the first source electrode 15B and the first semiconductor portion 15D. The first drain electrode 15C is disposed to overlap the other end-side portion (the right side in FIG. 4) of the first semiconductor portion 15D in the X-axis direction. The first drain electrode 15C and the first semiconductor portion 15D are connected to each other through a second contact hole CH2 that is opened to communicate with the gate insulating film 33 and the first interlayer insulating film 34 interposed therebetween. In other words, the second contact hole CH2 is at a connection position between the first drain electrode 15C and the first semiconductor portion 15D. The first source electrode 15B and the first drain electrode 15C are disposed at positions spaced apart from each other in the X-axis direction with the first gate electrode 15A interposed therebetween. The first contact hole CH1 and the second contact hole CH2 are disposed at positions spaced apart from each other in the X-axis direction with the first gate electrode 15A interposed therebetween.

Next, a cross-sectional configuration of the display region AA will be described in detail. As shown in FIG. 4, the second TFT 24 is disposed in the display region AA. The second TFT 24 includes a second gate electrode 24A, a second source electrode 24B, a second drain electrode 24C, and a second semiconductor portion 24D. Among these, the second semiconductor portion 24D is located on the lowermost layer side with respect to the electrodes 24A to 24C, and is constituted by the semiconductor film. Thus, the second TFT 24 can be said to be a top-gate type transistor, similar to the first TFT 15.

As shown in FIG. 4, the second gate electrode 24A is constituted by a portion of the second metal film 32 different from the first gate electrode 15A. The second gate electrode 24A is disposed to overlap the upper layer side of the second semiconductor portion 24D via the gate insulating film 33. The second gate electrode 24A is disposed to overlap the center-side portion of the second semiconductor portion 24D in the X-axis direction.

As shown in FIG. 4, the second source electrode 24B is constituted of a portion of the third metal film different from the first source electrode 15B and the first drain electrode 15C. The second drain electrode 24C is constituted of a portion of the third metal film different from the first source electrode 15B, the first drain electrode 15C and the second source electrode 24B. The second source electrode 24B and the second drain electrode 24C are disposed to overlap a portion of the first semiconductor portion 15D on the upper layer side via the gate insulating film 33 and the first interlayer insulating film 34. The second source electrode 24B is disposed to overlap one end-side portion (the left side in FIG. 4) of the second semiconductor portion 24D in the X-axis direction. The second source electrode 24B and the second semiconductor portion 24D are connected to each other through a third contact hole CH3 that is opened to communicate with the gate insulating film 33 and the first interlayer insulating film 34 interposed therebetween. The second drain electrode 24C is disposed to overlap the other end-side portion (the right side in FIG. 4) of the second semiconductor portion 24D in the X-axis direction. The second drain electrode 24C and the second semiconductor portion 24D are connected to each other through a fourth contact hole CH4 that is opened to communicate with the gate insulating film 33 and first interlayer insulating film 34 interposed therebetween. The second source electrode 24B and the second drain electrode 24C are disposed at positions spaced apart from each other in the X-axis direction with the second gate electrode 24A interposed therebetween.

As shown in FIG. 4, the pixel electrode 25 and the common electrode 28 (touch electrode 29) are disposed in the display region AA. The pixel electrode 25 is constituted of a second transparent electrode film. A portion of the pixel electrode 25 is disposed to overlap the second drain electrode 24C. The pixel electrode 25 and the second drain electrode 24C are connected to each other through a fifth contact hole CH5 that is opened to communicate with the flattening film 35, the second interlayer insulating film 36, the third interlayer insulating film 37, and the fourth interlayer insulating film 38 that are interposed therebetween. In addition, slits are opened in the plurality of pixel electrodes 25. The slits are not shown in FIG. 3.

The common electrode 28 is constituted of a first transparent electrode film. As shown in FIG. 4, the common electrode 28 is disposed to overlap all of the pixel electrodes 25 disposed in the display region AA on the lower layer side via the fourth interlayer insulating film 38. A common potential signal set to be at a common potential (reference potential) is supplied to the common electrode 28. When the pixel electrode 25 is charged to a potential based on an image signal transmitted to the source wiring line 26 in association with the driving of the second TFT 24, a potential difference is generated between the pixel electrode 25 and the common electrode 28. Then, a fringe electrical field (oblique electric field) is generated between an opening edge of the slit in the pixel electrode 25 and the common electrode 28, the fringe electric field including a component in a normal direction with respect to the plate surface of the array substrate 21 in addition to a component along the plate surface of the array substrate 21. Thus, it is possible to control the alignment state of the liquid crystal molecules included in the liquid crystal layer 22 by using this fringe electrical field, and a predetermined display is performed based on the alignment state of the liquid crystal molecules. That is, an operation mode of the liquid crystal panel 11 according to this embodiment is a fringe field switching (FFS) mode. An opening for preventing a short circuit with the pixel electrode 25 is provided in the common electrode 28 at a position overlapping the fifth contact hole CH5.

Further, as shown in FIG. 4, the touch wiring line 30 is disposed in the display region AA. The touch wiring line 30 is constituted of a fourth metal film. The touch wiring line 30 is disposed at a position overlapping the source wiring line 27 in a plan view. The flattening film 35 and the second interlayer insulating film 36 are interposed between the touch wiring line 30 and the source wiring line 27 that overlap each other, thereby maintaining a state where they are insulated from each other. The third interlayer insulating film 37 is interposed between the touch wiring line 30 and the common electrode 28. The touch wiring line 30 and the touch electrode 29 to be connected thereto are connected to each other through a sixth contact hole opened in the third interlayer insulating film 37 interposed therebetween. The sixth contact hole is not shown in the drawing.

Furthermore, in the display region AA, a light shielding portion 39 is provided at a position overlapping at least the entire region of the second semiconductor portion 24D. The light shielding portion 39 is constituted of a first metal film. The light shielding portion 39 is disposed to overlap the second semiconductor portion 24D on the lower layer side via the base coat film 31. Thus, the light shielding portion 39 can shield light that is emitted from the lower layer side from a backlight device to a channel region of the second semiconductor portion 24D. Thereby, it is possible to suppress fluctuations in the characteristics of the second TFT 24 that may occur when light is emitted to the channel region of the second semiconductor portion 24D.

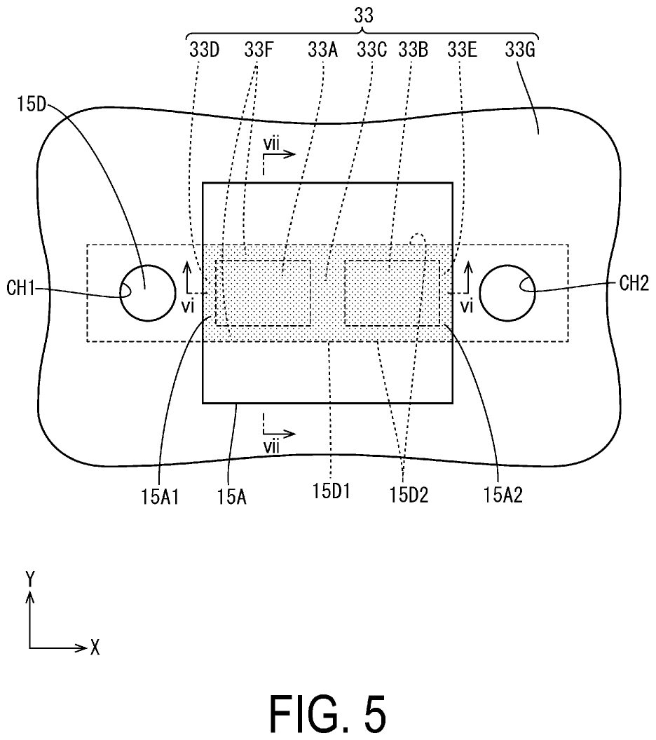

A detailed configuration of the first TFT 15 included in the circuit portion 14 will be described with reference to FIGS. 5 to 7. FIGS. 5 to 7 show only a configuration (first semiconductor portion 15D and gate insulating film 33) of the first TFT 15 on a lower layer side below the first gate electrode 15A. As shown in FIG. 5, the first semiconductor portion 15D included in the first TFT 15 extends in the X-axis direction (first direction). The first semiconductor portion 15D has a substantially rectangular shape that is horizontally elongated in a plan view. The first semiconductor portion 15D has a width dimension (dimension in the Y-axis direction) according to the amount of current flowing through a circuit to which the first TFT 15 belongs in the circuit portion 14.

As shown in FIG. 5, the first gate electrode 15A extends in the X-axis direction so as to be parallel to the first semiconductor portion 15D. The first gate electrode 15A has a substantially rectangular shape that is horizontally elongated in a plan view. The first gate electrode 15A has a length dimension (dimension in the X-axis direction) smaller than the width dimension of the first semiconductor portion 15D, and has a width dimension (dimension in the Y-axis direction) larger than the length dimension (dimension in the X-axis direction) of the first semiconductor portion 15D. The first gate electrode 15A extends in the Y-axis direction (second direction) and is disposed across the first semiconductor portion 15D so as to overlap the entire width of the first semiconductor portion 15D. Both end portions of the first gate electrode 15A in the width direction (Y-axis direction) are disposed not to overlap the first semiconductor portion 15D. The first gate electrode 15A is disposed to overlap the center-side portion of the first semiconductor portion 15D in the length direction (X-axis direction). Both end-side portions of the first semiconductor portion 15D in the longitudinal direction are disposed not to overlap the first gate electrode 15A. The first contact hole CH1 and the second contact hole CH2 are disposed to overlap the both end-side portions of the first semiconductor portion 15D in the longitudinal direction.

In this manner, the first TFT 15 according to this embodiment has a single-gate structure in which one first gate electrode 15A is disposed to overlap the first semiconductor portion 15D, as shown in FIG. 5. In a transistor having a single-gate structure in the related art, hot carrier injection is likely to occur when a high voltage is applied, thereby resulting in a concern that transistor performance may deteriorate over time. In particular, a high voltage is applied to the first TFT 15 belonging to the buffer circuit included in the circuit portion 14 as in this embodiment, and thus there is a concern that hot carrier injection may occur. In addition, in the transistor having a single-gate structure in the related art, ESD (Electro-Static Discharge) is likely to occur between an end portion of a gate electrode and a semiconductor portion, which may cause damage to the end portion of the gate electrode or the semiconductor portion resulting in a concern that a yield may be deteriorated.

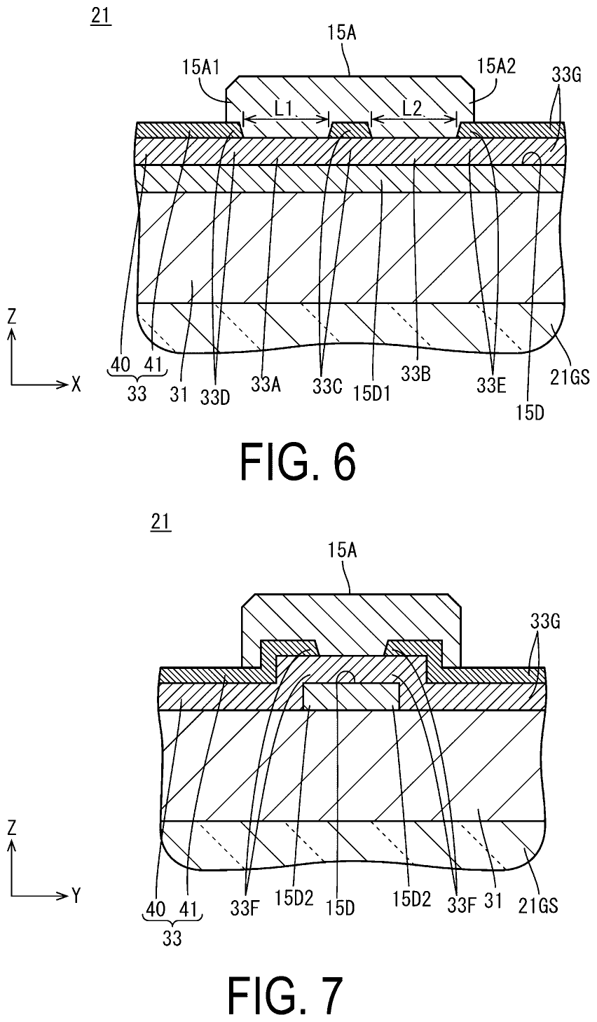

In this regard, in this embodiment, the gate insulating film 33 interposed between the first gate electrode 15A and the first semiconductor portion 15D is configured such that the film thickness thereof changes depending on its position in the X-axis direction (first direction) as shown in FIG. 6. That is, the gate insulating film 33 is configured such that a first thick portion 33A, a second thick portion 33B having the same film thickness as that of the first thick portion 33A, a third thick portion 33C having a film thickness larger than that of the first thick portion 33A, a fourth thick portion 33D having a film thickness larger than that of the first thick portion 33A, and a fifth thick portion 33E having a film thickness larger than that of the first thick portion 33A are lined up in the X-axis direction. The first thick portion 33A, the second thick portion 33B, the third thick portion 33C, the fourth thick portion 33D, and the fifth thick portion 33E are all disposed at positions that overlap both the first gate electrode 15A and the first semiconductor portion 15D.

Specifically, as shown in FIGS. 5 and 6, the first thick portion 33A and the second thick portion 33B are disposed at positions spaced apart from each other in the X-axis direction (first direction). The first thick portion 33A is disposed at a position spaced apart from the second thick portion 33B on the left side in FIG. 6. That is, it can be said that the first thick portion 33A is located closer to the first source electrode 15B (closer to the first contact holes CH1) than the third thick portion 33C described later in the X-axis direction, and the second thick portion 33B is located closer to the first drain electrodes 15C (closer to the second contact holes CH2) than the third thick portion 33C in the X-axis direction (see FIG. 4). Dimensions L1 and L2 of the first thick portion 33A and the second thick portion 33B in the X-axis direction are larger than any of the dimensions of the third thick portion 33C, the fourth thick portion 33D, and the fifth thick portion 33E in the X-axis direction. The dimension L1 of the first thick portion 33A in the X-axis direction and the dimension L2 of the second thick portion 33B in the X-axis direction are substantially equal to each other. The third thick portion 33C is disposed to be interposed between the first thick portion 33A and the second thick portion 33B in the X-axis direction. That is, a gap corresponding to the third thick portion 33C is provided between the first thick portion 33A and the second thick portion 33B. The third thick portion 33C is disposed to overlap the central portion of the first gate electrode 15A in the X-axis direction. The fourth thick portion 33D is disposed at a position overlapping one end portion 15A1 (on the left side in FIG. 6) of the first gate electrode 15A in the X-axis direction. The fourth thick portion 33D is disposed to sandwich the first thick portion 33A with the third thick portion 33C in the X-axis direction. The fifth thick portion 33E is disposed at a position overlapping the other end portion 15A2 (on the right side in FIG. 6) of the first gate electrode 15A in the X-axis direction. The fifth thick portion 33E is disposed to sandwich the second thick portion 33B with the third thick portion 33C in the X-axis direction. It can be said that the first thick portion 33A, the second thick portion 33B, and the third thick portion 33C are disposed to overlap a portion (center-side portion) of the first gate electrode 15A excluding both the end portions 15A1 and 15A2 in the X-axis direction.

In this embodiment, the film thicknesses of the first, second, third, fourth, and fifth thick portions 33A, 33B, 33C, 33D, and 33E are set to such sizes that a channel region 15D1 is formed in each of portions of the first semiconductor portion 15D which overlap the first, second, third, fourth, and fifth thick portions 33A, 33B, 33C, 33D, and 33E when a predetermined voltage (voltage equal to or higher than a threshold voltage) is applied to the first gate electrode 15A. That is, the voltage applied to the first gate electrode 15A is set to such a value that the channel region 15D1 is generated not only in portions of the first semiconductor portion 15D which overlap the first and second thick portions 33A and 33B having relatively small film thicknesses but also in portions overlapping the third, fourth, and fifth thick portions 33C, 33D, and 33E having relatively large film thicknesses. Thus, the channel region 15D1 is formed over substantially the entire region of the portion of the first semiconductor portion 15D that overlaps the first gate electrode 15A. In FIG. 5, a range in which the channel region 15D1 is generated in the first semiconductor portion 15D is shown in a shaded shape. However, an electric field intensity applied from the first gate electrode 15A to the first semiconductor portion 15D varies depending on the film thicknesses of the thick portions 33A to 33E. Specifically, an electric field intensity applied from the first gate electrode 15A to the portions of the first semiconductor portion 15D which overlap the first and second thick portions 33A and 33B having relatively small film thicknesses tends to become relatively high, and an electric field intensity applied from the first gate electrode 15A to the portions of the first semiconductor portion 15D which overlap the third, fourth and fifth thick portions 33C, 33D, and 33E having relatively large film thicknesses tends to become relatively low. The amount of current flowing through the channel region 15D1 tends to increase as the electric field intensity applied from the first gate electrode 15A becomes higher, and tends to decrease as the electric field intensity becomes lower. That is, it can be said that the portions of the channel region 15D1 which overlap the first thick portion 33A and the second thick portion 33B having a relatively small film thickness have a relatively low resistance, and the portions of the channel region 15D1 which overlap the third thick portion 33C, the fourth thick portion 33D, and the fifth thick portion 33E having a relatively large film thickness have a relatively high resistance.

According to such a configuration, when a predetermined voltage is applied to the first gate electrode 15A, the channel region 15D1 is generated in the first semiconductor portion 15D. Thus, electrons move between the first source electrode 15B and the first drain electrode 15C via the channel region 15D1. Here, the gate insulating film 33 interposed between the first gate electrode 15A and the first semiconductor portion 15D includes the first thick portion 33A, the second thick portion 33B having the same film thickness as that of the first thick portion 33A, the third thick portion 33C having a film thickness larger than that of the first thick portion 33A, the fourth thick portion 33D having a film thickness larger than that of the first thick portion 33A, and the fifth thick portion 33E having a film thickness larger than that of the first thick portion 33A. Among these, the first thick portion 33A, the second thick portion 33B, and the third thick portion 33C are all disposed to overlap both the first gate electrode 15A and the first semiconductor portion 15D, and the third thick portion 33C is disposed to be interposed between the first thick portion 33A and the second thick portion 33B in the X-axis direction. Thus, the amount of current flowing through the portion of the channel region 15D1 which overlaps the third thick portion 33C is smaller than the amount of current flowing through the portions of the channel region 15D1 which overlap the first thick portion 33A and the second thick portion 33B. Thereby, the occurrence of hot carrier injection is suppressed, and deterioration of transistor performance over time can be suppressed. In addition, since the fourth thick portion 33D and the fifth thick portion 33E are disposed to overlap both the end portions 15A1 and 15A2 of the first gate electrode 15A in the X-axis direction and the first semiconductor portion 15D, ESD is less likely to occur between the end portions 15A1 and 15A2 of the first gate electrode 15A in the X-axis direction and the first semiconductor portion 15D. Thereby, damage to the end portions 15A1 and 15A2 of the first gate electrodes 15A in the X-axis direction and the first semiconductor portion 15D due to the ESD is less likely to occur, thereby improving a yield. In addition, since the first thick portion 33A and the second thick portion 33B have the same dimension in the X-axis direction, the lengths of the portions overlapping the first thick portion 33A and the second thick portion 33B in the channel region 15D1 generated in the first semiconductor portion 15D are equal to each other in the X-axis direction, and the resistances of the portions are equal to each other. In addition, the first TFT 15 according to this embodiment has a single-gate structure, a length in the X-axis direction from the first source electrode 15B to the first drain electrode 15C is smaller than that of a TFT having a double-gate structure (multi-gate structure), which is suitable for miniaturization of the first TFT 15.

As shown in FIG. 6, the gate insulating film 33 has a layered structure of a lower insulating film 40 and an upper insulating film 41. The lower insulating film 40 is disposed on the upper layer side of the first semiconductor portion 15D. The lower insulating film 40 is made of, for example, SiO₂ and has a film thickness of, for example, approximately 100 nm. The upper insulating film 41 is located on the upper layer side of the lower insulating film 40 and disposed on the lower layer side of the first gate electrode 15A. The upper insulating film 41 is made of a material different from that of the lower insulating film 40. The upper insulating film 41 has a film thickness smaller than that of the lower insulating film 40. The upper insulating film 41 is made of, for example, SiN and has a film thickness of, for example, approximately 50 nm. In this manner, the gate insulating film 33 is formed to have a layered structure of the lower insulating film 40 and the upper insulating film 41, which are made of different materials, and thus the first thick portion 33A, the second thick portion 33B, the third thick portion 33C, the fourth thick portion 33D, and the fifth thick portion 33E, which have different film thicknesses, can be easily provided.

In this embodiment, the first thick portion 33A and the second thick portion 33B are constituted by the lower insulating film 40 as shown in FIG. 6. On the other hand, the third thick portion 33C, the fourth thick portion 33D, and the fifth thick portion 33E are constituted by the upper insulating film 41 and the lower insulating film 40. That is, the third thick portion 33C, the fourth thick portion 33D, and the fifth thick portion 33E have the same film thickness. According to such a configuration, in the manufacturing process, the first thick portion 33A and the second thick portion 33B, which are constituted by the lower insulating film 40, and the third thick portion 33C, the fourth thick portion 33D, and the fifth thick portion 33E, which are constituted by the lower insulating film 40 and the upper insulating film 41, can be easily provided by sequentially forming the lower insulating film 40 and the upper insulating film 41 and then selectively removing the upper insulating film 41. In addition, the manufacturing is facilitated as compared to a case where the film thicknesses of the third thick portion 33C, the fourth thick portion 33D, and the fifth thick portion 33E are all different from each other.

In addition, as shown in FIG. 7, the gate insulating film 33 includes a sixth thick portion 33F having a film thickness larger than that of the first thick portion 33A. The sixth thick portion 33F is disposed to overlap an end portion 15D2 of the first semiconductor portion 15D in the Y-axis direction (the second direction intersecting the first direction). The sixth thick portion 33F has the same film thickness as those of the third thick portion 33C, the fourth thick portion 33D, and the fifth thick portion 33E. That is, the sixth thick portion 33F is constituted by the upper insulating film 41 and the lower insulating film 40, similar to the third thick portion 33C, the fourth thick portion 33D, and the fifth thick portion 33E.

In addition, as shown in FIGS. 6 and 7, the gate insulating film 33 includes a seventh thick portion 33G having a film thickness larger than that of the first thick portion 33A. The seventh thick portion 33G constitutes a portion of the gate insulating film 33 which does not overlap both the first gate electrode 15A and the first semiconductor portion 15D in a plan view. The seventh thick portion 33G has the same film thickness as those of the third thick portion 33C, the fourth thick portion 33D, the fifth thick portion 33E, and the sixth thick portion 33F. That is, the seventh thick portion 33G is constituted by the upper insulating film 41 and the lower insulating film 40, similar to the third thick portion 33C, the fourth thick portion 33D, the fifth thick portion 33E, and the sixth thick portion 33F.

This embodiment has the above-described structure, and a manufacturing method for the liquid crystal panel 11 will be subsequently described. The manufacturing method for the liquid crystal panel 11 includes a counter substrate manufacturing step (CF substrate manufacturing step) of manufacturing the counter substrate 20, an array substrate manufacturing step of manufacturing the array substrate 21, and a bonding step of bonding the manufactured counter substrate 20 and array substrate 21 together. Hereinafter, among the above steps, the array substrate manufacturing step will be described.

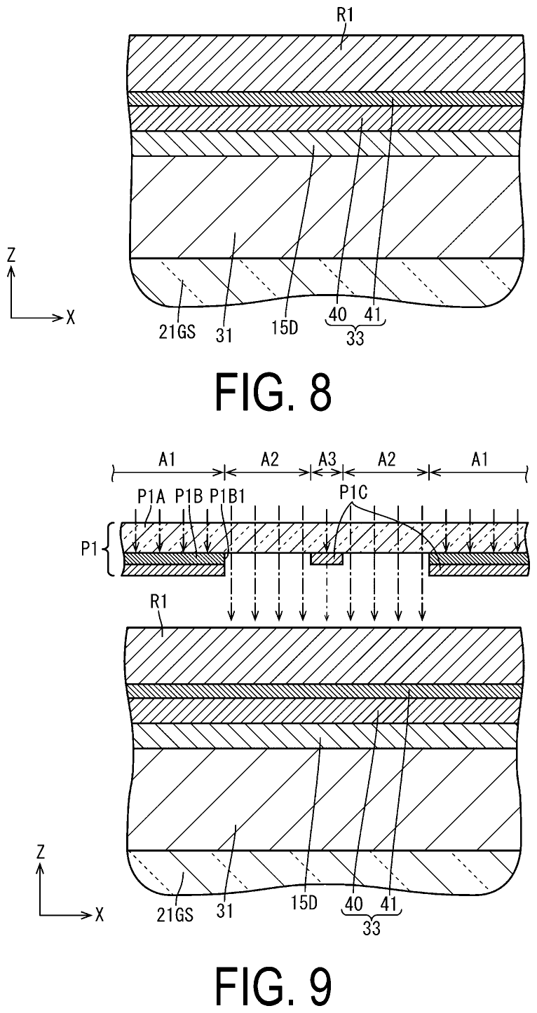

The array substrate manufacturing step includes at least a first step of forming and patterning the first metal film, a second step of forming the base coat film 31, a third step of forming the semiconductor film, performing a laser crystallization process, and then patterning the semiconductor film, a fourth step of forming and patterning the gate insulating film 33, a fifth step of forming and patterning the second metal film 32, a sixth step of forming and patterning the first interlayer insulating film 34, a seventh step of forming and patterning the third metal film, an eighth step of forming the flattening film 35, a ninth step of forming the second interlayer insulating film 36, a tenth step of forming and patterning the fourth metal film, an eleventh step of forming the third interlayer insulating film 37, a twelfth step of forming and patterning the first transparent electrode film, a thirteenth step of forming and patterning the fourth interlayer insulating film 38, a fourteenth step of forming and patterning the second transparent electrode film, and a fifteenth step of forming the alignment film and performing an alignment process. Among these, the fourth and fifth steps will be described in detail below with reference to FIGS. 8 to 16. FIGS. 8 to 16 show the same cross-sectional configuration as that in FIG. 6.

The term “patterning” described above means a process of a film based on a general photolithography method. Specifically, the process, that is, the patterning of a film to be processed is performed by forming a photoresist film on the film to be processed, exposing the photoresist film with an exposure device through a photomask having a predetermined pattern, developing the photoresist film, and performing etching through the developed photoresist film.

In the fourth step, as shown in FIG. 8, the lower insulating film 40 constituting the gate insulating film 33 is first formed in a solid state on the upper layer side of the first semiconductor portion 15D, then the upper insulating film 41 is formed in a solid state on the upper layer side of the lower insulating film 40, and then the first resist film R1 is formed in a solid state on the upper layer side of the upper insulating film 41. Thereafter, the first resist film R1 is exposed using an exposure device and the first photomask P1 shown in FIG. 9 (first exposure step). The first resist film R1 used in the fourth step is made of a positive photosensitive material. Here, the first photomask P1 will be described. As shown in FIG. 9, the first photomask P1 includes a transparent first base material P1A with sufficiently high light transmittance, a first light shielding film P1B formed on the main surface of the first base material P1A, and a semi-transmissive film PIC formed on the main surface of the first base material P1A and partially layered on the first light shielding film P1B. In other words, the first photomask P1 is a so-called half-tone mask. The first light shielding film P1B blocks exposure light from a light source of the exposure device, and the transmittance of the exposure light is approximately 0%. The first light shielding film P1B has a partial opening P1B1. The opening P1B1 has a size equal to or larger than the resolution of the exposure device, and can transmit light in its formation range. The semi-transmissive film PIC transmits the exposure light emitted from the light source of the exposure device with a predetermined transmittance. The semi-transmissive film PIC has a transmittance of exposure light, which is higher than the transmittance of the exposure light of the first light shielding film P1B, and is, for example, approximately 10% to 70%.

As shown in FIG. 9, the first light shielding film P1B is configured such that a plurality of openings P1B1 are disposed in each of an island-shaped area that overlaps a formation position for the first semiconductor portions 15D to be formed in the non-display region NAA, and in an island-shaped area that overlaps a formation position for the second semiconductor portions 24D to be formed in the display region AA. The semi-transmissive film PIC is disposed in an area overlapping a portion of each opening P1B1 disposed in the non-display region NAA, in addition to an area overlapping the first light shielding film P1B. Specifically, the semi-transmissive film P1C is disposed in an area overlapping a formation position for the third thick portion 33C of the gate insulating film 33 to be formed in the non-display region NAA. On the other hand, in the non-display region NAA, the first light shielding film P1B is disposed in an area where an opening edge portion of the opening P1B1 overlaps formation positions for the fourth thick portion 33D to be formed, the fifth thick portion 33E, and the sixth thick portion 33F of the gate insulating film 33, and is disposed in an area where portions other than the opening edge portion of the opening P1B1 overlap a formation position for the seventh thick portion 33G to be formed.

As shown in FIG. 9, in the first photomask P1, an area in which the first light shielding film P1B is formed is a first light shielding region A1 in which light is blocked. The transmittance of light in the first light shielding region A1 is approximately 0%. In the first photomask P1, a portion of the formation area for the opening P1B1, which does not overlap the semi-transmissive film PIC, is a first transmissive region A2 in which light is transmitted. Two first transmissive regions A2 are disposed at positions spaced apart from each other in the Y-axis direction (positions that overlap the formation positions for the first thick portion 33A to be formed and the second thick portion 33B) at formation positions for the first semiconductor portions 15D to be formed. The transmittance of light in the first transmissive region A2 is approximately 100%. In the first photomask P1, a portion of the formation area for the opening P1B1, which overlaps the semi-transmissive film PIC, is a semi-transmissive region A3 where light is half transmitted. One semi-transmissive region A3 is disposed at the center position (position that overlaps the formation position for the third thick portion 33C) to be formed in the Y-axis direction at the formation position for each first semiconductor portion 15D to be formed. That is, the first transmissive regions A2 and the semi-transmissive regions A3 are disposed lined up alternately in the Y-axis direction at the formation positions for the first semiconductor portions 15D to be formed. The transmittance of light in the semi-transmissive region A3 is higher than the transmittance in the first light shielding region A1 and lower than the transmittance in the first transmissive region A2, and is, for example, approximately 10% to 70%. The first light shielding regions A1, the first transmissive regions A2 and the semi-transmissive regions A3 constitute an exposure pattern in the first photomask P1.

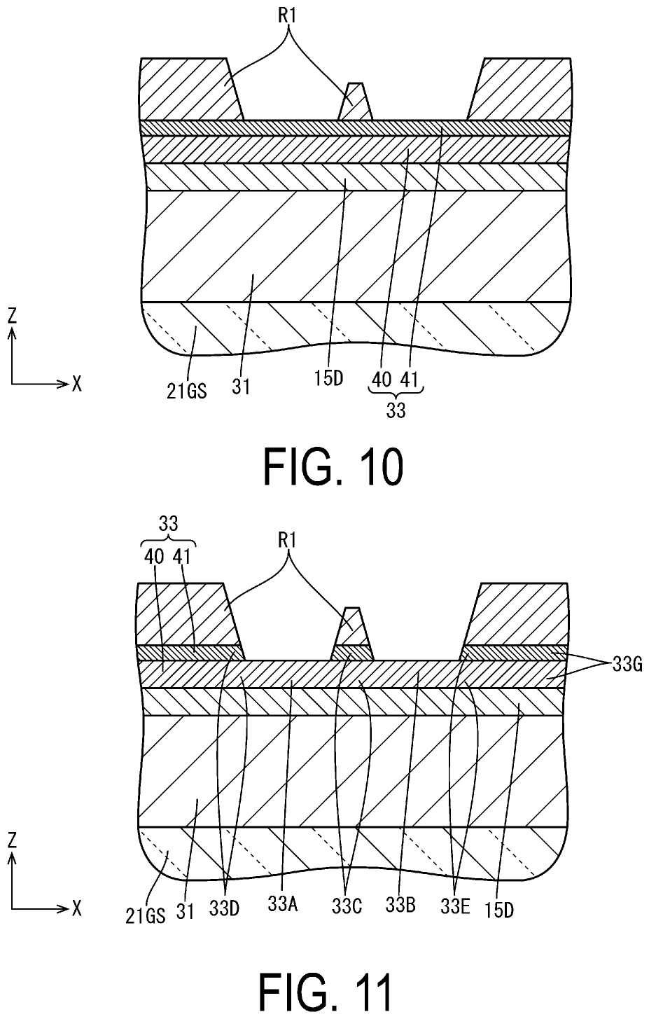

In the fourth step, the first resist film R1 is irradiated with exposure light emitted from the light source of the exposure device through the first photomask P1 configured as described above. The amount of exposure of the first resist film R1 is different for each portion overlapping each of the regions A1 to A3 of the first photomask P1, as shown in FIG. 9. That is, in the first resist film R1, the portion overlapping the first light shielding region A1 is hardly exposed and is left unexposed, the portion overlapping the first transmissive region A2 is sufficiently exposed, and the portion overlapping the semi-transmissive region A3 is exposed with a smaller amount of light than the portion overlapping the first light shielding region A1. The first resist film R1 used in the fourth step is made of a positive photosensitive material. Thus, when the first resist film R1 is developed after the exposure (first development step), as shown in FIG. 10, the light exposed portion (the portion overlapping the first transmissive region A2) of the first resist film R1 is removed, the light unexposed portion (the portion overlapping the first light shielding region A1) remains, and the semi-light exposed portion (the portion overlapping the semi-transmissive region A3) remains with a film thickness corresponding to the amount of exposure, that is, a film thickness smaller than that of the light unexposed portion. In this manner, in the first resist film R1, portions overlapping the first light shielding region A1 and the semi-transmissive region A3 in the first photomask P1 selectively remain.

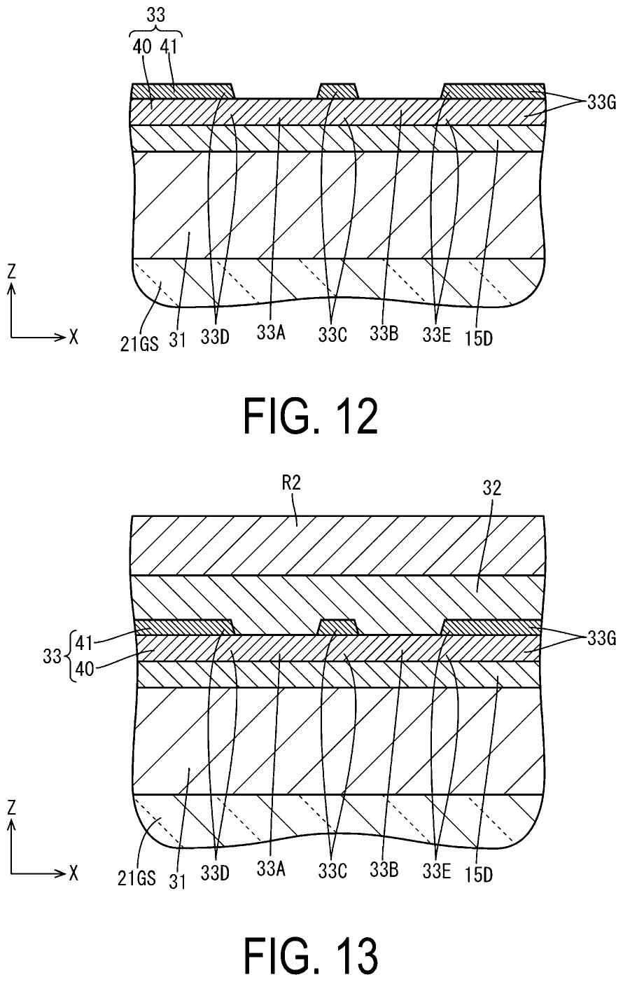

The gate insulating film 33 is etched using the first resist film R1 developed in this manner as a mask (first etching step). In this etching, etching conditions (such as the type of etching gas in the case of dry etching, and such as the type of etching solution in the case of wet etching) are set such that an etching rate for the upper insulating film 41 constituting the gate insulating film 33 is high and an etching rate for the lower insulating film 40 is low. When the first etching step is performed, as shown in FIG. 11, in the upper insulating film 41 constituting the gate insulating film 33, a portion that is exposed without being covered with the first resist film R1 (an area overlapping the first transmissive region A2 of the first photomask P1) is selectively removed, but a portion that is covered with the first resist film R1 (an area overlapping the first light shielding region A1 and the semi-transmissive region A3 of the first photomask P1) remains unremoved. The lower insulating film 40 constituting the gate insulating film 33 is not entirely removed, inclusive of an area overlapping the first transmissive region A2. Thereby, in the gate insulating film 33, it is possible to easily provide the first thick portion 33A and the second thick portion 33B which are located in areas overlapping the first transmissive region A2 of the first photomask P1 and constituted by the lower insulating film 40, the third thick portion 33C located in an area overlapping the semi-transmissive region A3 and constituted by the lower insulating film 40 and the upper insulating film 41, and the fourth thick portion 33D, the fifth thick portion 33E, the sixth thick portion 33F, and the seventh thick portion 33G which are located in an area overlapping the first light shielding region A1 and are all constituted by the lower insulating film 40 and the upper insulating film 41. When the etching is terminated, the first resist film R1 is removed by ashing (first ashing step), as shown in FIG. 12.

After the fourth step is performed as described above, the fifth step is performed. In the fifth step, as shown in FIG. 13, the second metal film 32 is formed in a solid state on the upper layer side of the gate insulating film 33, and then the second resist film R2 is formed in a solid state on the upper layer side of the second metal film 32. The second resist film R2 used in the fifth step is made of a negative photosensitive material. Then, the second resist film R2 is exposed using an exposure device and the first photomask P1 (second exposure step). The first photomask P1 used in the second exposure step of the fifth step has the same exposure pattern (the first light shielding region A1, the first transmissive region A2 and the semi-transmissive region A3) as that of the first photomask P1 used in the first exposure step of the fourth step described above. In this manner, the first photomask P1 having the same exposure pattern can be used in the first exposure step of exposing the first resist film R1 and the second exposure step of exposing the second resist film R2, which is suitable for reducing costs associated with the equipment required for manufacturing.

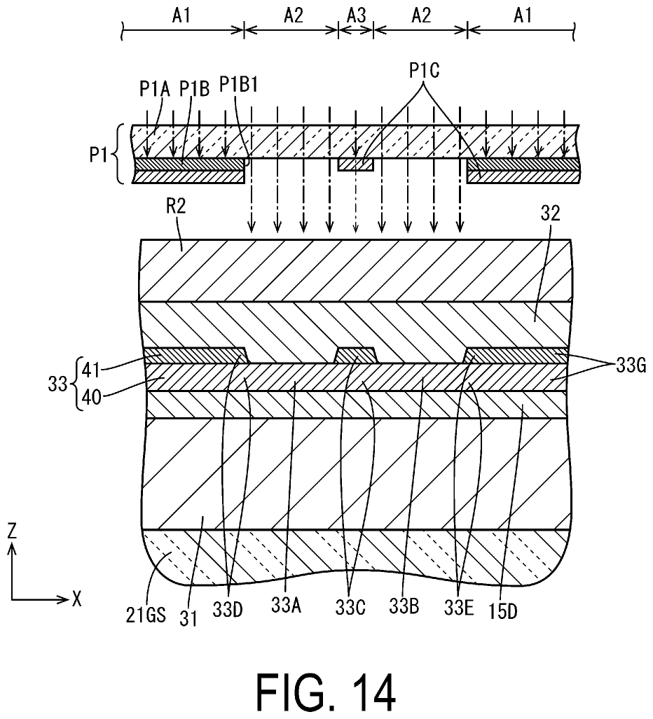

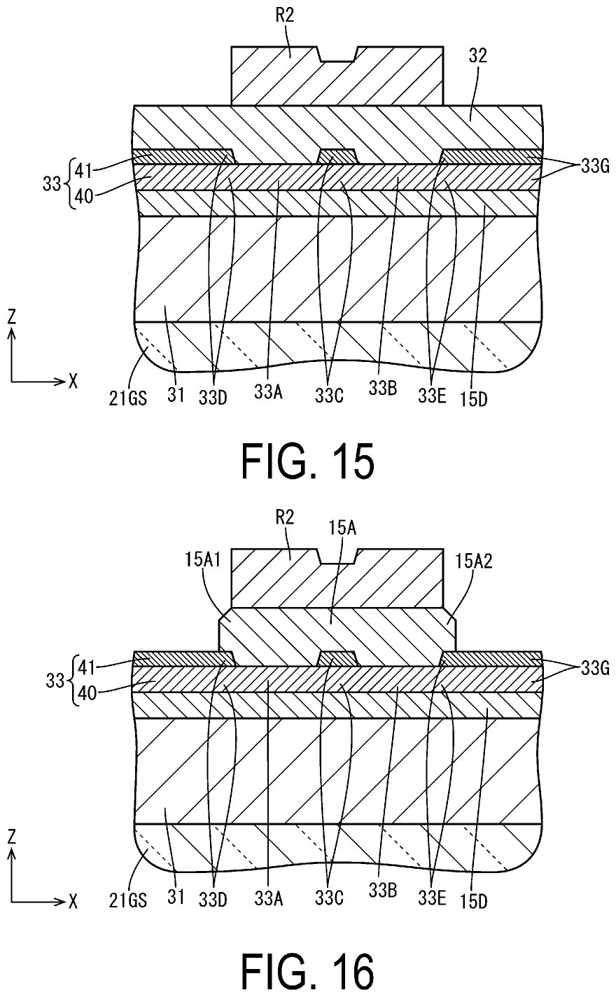

In the fifth step, the second resist film R2 is irradiated with exposure light emitted from the light source of the exposure device through the first photomask P1 having the same exposure pattern as the first photomask P1 used in the first exposure step of the fourth step. As shown in FIG. 14, the amount of exposure of the second resist film R2 is different for each portion overlapping each of the regions A1 to A3 of the first photomask P1. That is, in the second resist film R2, the portion overlapping the first light shielding region A1 is hardly exposed, the portion overlapping the first transmissive region A2 is sufficiently exposed, and the portion overlapping the semi-transmissive region A3 is exposed with a smaller amount of light than the portion overlapping the first transmissive region A2. The second resist film R2 used in the fifth step is made of a negative photosensitive material. Thus, when the second resist film R2 is developed after the exposure (second development step), as shown in FIG. 15, the light unexposed portion (the portion overlapping the first light shielding region A1) of the second resist film R2 is removed, the light exposed portion (the portion overlapping the first transmissive region A2) remains, and the semi-light exposed portion (the portion overlapping the semi-transmissive region A3) remains with a film thickness corresponding to the amount of exposure, that is, a film thickness smaller than that of the light exposed portion. In this manner, in the second resist film R2, portions overlapping the first transmissive region A2 and the semi-transmissive region A3 in the first photomask P1 selectively remain.

When the second metal film 32 is etched using the second resist film R2, which is developed in this manner, as a mask (second etching step), the first gate electrode 15A located in an area overlapping the first transmissive region A2 and the semi-transmissive region A3 of the first photomask P1 is provided as shown in FIG. 16. The first gate electrode 15A provided through the second etching step is disposed such that both the end portions 15A1 and 15A2 overlap the fourth and fifth thick portions 33D and 33E of the gate insulating film 33 in the X-axis direction, and the center-side portion between both the end portions 15A1 and 15A2 overlaps the first thick portion 33A, the second thick portion 33B, and the third thick portion 33C of the gate insulating film 33. When the etching is terminated, the second resist film R2 is removed by ashing as shown in FIG. 6 (second ashing step). When the sixth step is performed after the fifth step is terminated in this manner, the first interlayer insulating film 34 is formed on the upper layer side of the first gate electrode 15A and then patterned (see FIG. 4).

As described above, the first TFT (transistor) 15 of this embodiment includes the first semiconductor portion (semiconductor portion) 15D extending in the first direction and made of a semiconductor material, the first gate electrode (first electrode) 15A disposed overlapping a portion of the first semiconductor portion 15D, the gate insulating film (first insulating film) 33 interposed between the first gate electrode 15A and the first semiconductor portion 15D, the first source electrode (second electrode) 15B disposed overlapping a portion of the first semiconductor portion 15D and connected to the first semiconductor portion 15D, and the first drain electrode (third electrode) 15C disposed overlapping a portion of the first semiconductor portion 15D at a position spaced apart from a connection position between the first source electrode 15B and the first semiconductor portion 15D in the first direction and connected to the first semiconductor portion 15D. The gate insulating film 33 includes the first thick portion 33A, the second thick portion 33B having the same film thickness as that of the first thick portion 33A, the third thick portion 33C having a film thickness larger than that of the first thick portion 33A, the fourth thick portion 33D having a film thickness larger than that of the first thick portion 33A, and the fifth thick portion 33E having a film thickness larger than that of the first thick portion 33A. The first thick portion 33A is disposed at a position overlapping both the first gate electrode 15A and the first semiconductor portion 15D, the second thick portion 33B overlaps both the first gate electrode 15A and the first semiconductor portion 15D and disposed at a position spaced apart from the first thick portion 33A in the first direction, the third thick portion 33C overlaps both the first gate electrode 15A and the first semiconductor portion 15D and disposed to be interposed between the first thick portion 33A and the second thick portion 33B in the first direction, the fourth thick portion 33D is disposed overlapping both one end portion 15A1 of the first gate electrode 15A in the first direction and the first semiconductor portion 15D, and the fifth thick portion 33E is disposed overlapping both the other end portion 15A2 of the first gate electrode 15A in the first direction and the first semiconductor portion 15D.

When a voltage equal to or greater than a threshold voltage of the first TFT 15 is applied to the first gate electrode 15A, the channel region 15D1 is generated in the first semiconductor portion 15D. Thus, electrons move between the first source electrode 15B and the first drain electrode 15C via the channel region 15D1. Here, the gate insulating film 33 interposed between the first gate electrode 15A and the first semiconductor portion 15D includes the first thick portion 33A, the second thick portion 33B having the same film thickness as that of the first thick portion 33A, the third thick portion 33C having a film thickness larger than that of the first thick portion 33A, the fourth thick portion 33D having a film thickness larger than that of the first thick portion 33A, and the fifth thick portion 33E having a film thickness larger than that of the first thick portion 33A. Among these, the first thick portion 33A, the second thick portion 33B, and the third thick portion 33C are disposed overlapping both the first gate electrode 15A and the first semiconductor portion 15D, and the third thick portion 33C is disposed to be interposed between the first thick portion 33A and the second thick portion 33B in the first direction. Thus, the amount of current flowing through the portion of the channel region 15D1 which overlaps the third thick portion 33C is smaller than the amount of current flowing through the portion of the channel region 15D1 which overlaps the first thick portion 33A and the second thick portion 33B. Thereby, the occurrence of hot carrier injection is suppressed, and deterioration of transistor performance over time can be suppressed. In addition, since the fourth thick portion 33D and the fifth thick portion 33E are disposed overlapping both the end portions 15A1 and 15A2 of the first gate electrode 15A in the first direction and the first semiconductor portion 15D, ESD is less likely to occur between the end portions 15A1 and 15A2 of the first gate electrode 15A in the first direction and the first semiconductor portion 15D. Thereby, damage to the end portions 15A1 and 15A2 of the first gate electrodes 15A in the first direction and the first semiconductor portion 15D due to the ESD is less likely to occur, thereby improving a yield.

Furthermore, the gate insulating film 33 has a layered structure of the lower insulating film 40 disposed on the upper layer side of the first semiconductor portion 15D, and the upper insulating film 41 disposed on the upper layer side of the lower insulating film 40 and made of a material different from that of the lower insulating film 40. In this manner, the gate insulating film 33 is formed to have a layered structure of the lower insulating film 40 and the upper insulating film 41, which are made of different materials, and thus the first thick portion 33A, the second thick portion 33B, the third thick portion 33C, the fourth thick portion 33D, and the fifth thick portion 33E, which have different film thicknesses, can be easily provided.

In addition, the third thick portion 33C, the fourth thick portion 33D, and the fifth thick portion 33E have the same film thickness. The manufacturing is facilitated as compared to a case where the film thicknesses of the third thick portion 33C, the fourth thick portion 33D, and the fifth thick portion 33E are all different from each other.

In addition, the dimensions L1 and L2 of the first thick portion 33A and the second thick portion 33B in the first direction are the same. Thereby, the lengths of the portions overlapping the first thick portion 33A and the second thick portion 33B in the channel region 15D1 generated in the first semiconductor portion 15D are equal to each other in the first direction.

In addition, for the first semiconductor portion 15D, a polysilicon semiconductor material is used as a semiconductor material. As compared to a case where an amorphous silicon semiconductor material or an oxide semiconductor material is used as a semiconductor material, high electron mobility can be obtained.

Further, a manufacturing method for the first TFT 15 according to this embodiment includes forming a semiconductor film made of a semiconductor material; patterning the semiconductor film to provide the first semiconductor portion 15D extending in the first direction; forming the gate insulating film 33 on the upper layer side of the first semiconductor portion 15D; forming the first resist film R1 made of a photosensitive material on the upper layer side of the gate insulating film 33; exposing and developing the first resist film R1; etching the gate insulating film 33 using the first resist film R1 as a mask to provide the first thick portion 33A disposed overlapping the first semiconductor portion 15D, the second thick portion 33B disposed overlapping the first semiconductor portion 15D, disposed at a position spaced apart from the first thick portion 33A in the first direction, and having the same film thickness as that of the first thick portion 33A, the third thick portion 33C disposed to be interposed between the first thick portion 33A and the second thick portion 33B in the first direction at a position overlapping the first semiconductor portion 15D and having a film thickness larger than that of the first thick portion 33A, the fourth thick portion 33D overlapping the first semiconductor portion 15D, disposed to sandwich the first thick portion 33A with the third thick portion 33C in the first direction, and having a film thickness larger than that of the first thick portion 33A, and the fifth thick portion 33E overlapping the first semiconductor portion 15D, disposed to sandwich the second thick portion 33B with the third thick portion 33C in the first direction, and having a film thickness larger than that of the first thick portion 33A; forming the second metal film (first conductive film) 32 on the upper layer side of the gate insulating film 33; forming the second resist film R2 made of a photosensitive material on the upper layer side of the second metal film 32; exposing and developing the second resist film R2; etching the second metal film 32 using the second resist film R2 as a mask to provide the first gate electrode 15A in which one end portion 15A1 in the first direction overlaps the fourth thick portion 33D, the other end portion 15A2 in the first direction overlaps the fifth thick portion 33E, and a portion between both end portions in the first direction overlaps the first thick portion 33A, the second thick portion 33B, and the third thick portion 33C; forming the third metal film (second conductive film) on the upper layer side of the first gate electrode 15A; and patterning the third metal film to provide the first source electrode 15B disposed overlapping a portion of the first semiconductor portion 15D and connected to the first semiconductor portion 15D, and the first drain electrode 15C disposed overlapping a portion of the first semiconductor portion 15D at a position spaced apart in the first direction from a connection position between the first source electrode 15B and the first semiconductor portion 15D and connected to the first semiconductor portion 15D.

The first semiconductor portion 15D is provided by forming and patterning a semiconductor film. After the gate insulating film 33 and the first resist film R1 are sequentially formed on the upper layer side of the first semiconductor portion 15D, the first resist film R1 is exposed and developed. When the gate insulating film 33 is etched through the patterned first resist film R1, the first thick portion 33A, the second thick portion 33B, the third thick portion 33C, the fourth thick portion 33D, and the fifth thick portion 33E are provided. After the second metal film 32 and the second resist film R2 are sequentially formed on the upper layer side of the gate insulating film 33, the second resist film R2 is exposed and developed. When the second metal film 32 is etched through the patterned second resist film R2, the first gate electrode 15A is provided. The first source electrode 15B and the first drain electrode 15C are provided by forming and patterning the third metal film on the upper layer side of the first gate electrode 15A.

When a voltage equal to or greater than a threshold voltage of the first TFT 15 manufactured in this manner is applied to the first gate electrode 15A, the channel region 15D1 is generated in the first semiconductor portion 15D. Thus, electrons move between the first source electrode 15B and the first drain electrode 15C via the channel region 15D1. Here, the gate insulating film 33 interposed between the first gate electrode 15A and the first semiconductor portion 15D includes the first thick portion 33A, the second thick portion 33B having the same film thickness as that of the first thick portion 33A, the third thick portion 33C having a film thickness larger than that of the first thick portion 33A, the fourth thick portion 33D having a film thickness larger than that of the first thick portion 33A, and the fifth thick portion 33E having a film thickness larger than that of the first thick portion 33A. Among these, the first thick portion 33A, the second thick portion 33B, and the third thick portion 33C are disposed overlapping both the first gate electrode 15A and the first semiconductor portion 15D, and the third thick portion 33C is disposed to be interposed between the first thick portion 33A and the second thick portion 33B in the first direction. Thus, the amount of current flowing through the portion of the channel region 15D1 which overlaps the third thick portion 33C is smaller than the amount of current flowing through the portion of the channel region 15D1 which overlaps the first thick portion 33A and the second thick portion 33B. Thereby, the occurrence of hot carrier injection is suppressed, and deterioration of transistor performance over time can be suppressed. In addition, since the fourth thick portion 33D and the fifth thick portion 33E are disposed overlapping both the end portions 15A1 and 15A2 of the first gate electrode 15A in the first direction and the first semiconductor portion 15D, ESD is less likely to occur between the end portions 15A1 and 15A2 of the first gate electrode 15A in the first direction and the first semiconductor portion 15D. Thereby, damage to the end portions 15A1 and 15A2 of the first gate electrodes 15A in the first direction and the first semiconductor portion 15D due to the ESD is less likely to occur, thereby improving a yield.

In addition, the first resist film R1 made of a positive photosensitive material is formed on the upper layer side of the gate insulating film 33, the first resist film R1 is exposed and then developed through the first photomask P1 having the first light shielding region A1 disposed overlapping formation areas for the fourth thick portion 33D and the fifth thick portion 33E to block light to be formed, the first transmissive region A2 overlapping formation areas for the first thick portion 33A and the second thick portion 33B to be formed to transmit light, and the semi-transmissive region A3 overlapping a formation area for the third thick portion 33C to be formed, disposed to be interposed between two first transmissive regions A2 in the first direction, and having a light transmittance higher than that of the first light shielding region A1 and lower than that of the first transmissive region A2, the second resist film R2 made of a negative photosensitive material is formed on the upper layer side of the second metal film 32, and the second resist film R2 is exposed and then developed through the first photomask P1.

The first resist film R1 formed on the upper layer side of the gate insulating film 33 is exposed through the first photomask P1. The amount of exposure of the first resist film R1 is different for each portion overlapping each region of the first photomask P1. That is, in the first resist film R1, a portion overlapping the first light shielding region A1 is hardly exposed, a portion overlapping the first transmissive region A2 is sufficiently exposed, and a portion overlapping the semi-transmissive region A3 is exposed with a smaller amount of light than the portion overlapping the first transmissive region A2. The first resist film R1 is made of a positive photosensitive material, and thus, when the first resist film R1 is developed, the light exposed portion (the portion overlapping the first transmissive region A2) is removed, the light unexposed portion (the portion overlapping the first light shielding region A1) remains, and the semi-light exposed portion (the portion overlapping the semi-transmissive region A3) remains with a film thickness corresponding to the amount of exposure. The gate insulating film 33 is etched using the developed first resist film R1 as a mask, thereby providing the first thick portion 33A and the second thick portion 33B located in an area overlapping the first transmissive region A2 of the first photomask P1, the third thick portion 33C located in an area overlapping the semi-transmissive region A3, and the fourth thick portion 33D and the fifth thick portion 33E located in an area overlapping the first light shielding region A1.

The second resist film R2 formed on the upper layer side of the second metal film 32 is exposed through the first resist film R1 having the same exposure pattern as that of the first photomask P1 used when the first photomask P1 is exposed. The amount of exposure of the second resist film R2 is different for each portion overlapping each region of the first photomask P1. That is, in the second resist film R2, a portion overlapping the first light shielding region A1 is hardly exposed, a portion overlapping the first transmissive region A2 is sufficiently exposed, and a portion overlapping the semi-transmissive region A3 is exposed with a smaller amount of light than that of the portion overlapping the first transmissive region A2. The second resist film R2 is made of a negative photosensitive material, and thus, when the second resist film R2 is developed, the light unexposed portion (the portion overlapping the first light shielding region A1) is removed, the light exposed portion (the portion overlapping the first transmissive region A2) remains, and the semi-light exposed portion (the portion overlapping the semi-transmissive region A3) remains with a film thickness corresponding to the amount of exposure. The second metal film 32 is etched using the developed second resist film R2 as a mask, thereby providing the first gate electrode 15A located in an area overlapping the first transmissive region A2 and the semi-transmissive region A3 of the first photomask P1.

As described above, the first photomask P1 having the same exposure pattern can be used in the step of exposing the first resist film R1 and the step of exposing the second resist film R2, which is suitable for reducing costs associated with the equipment required for manufacturing.

### Second Embodiment

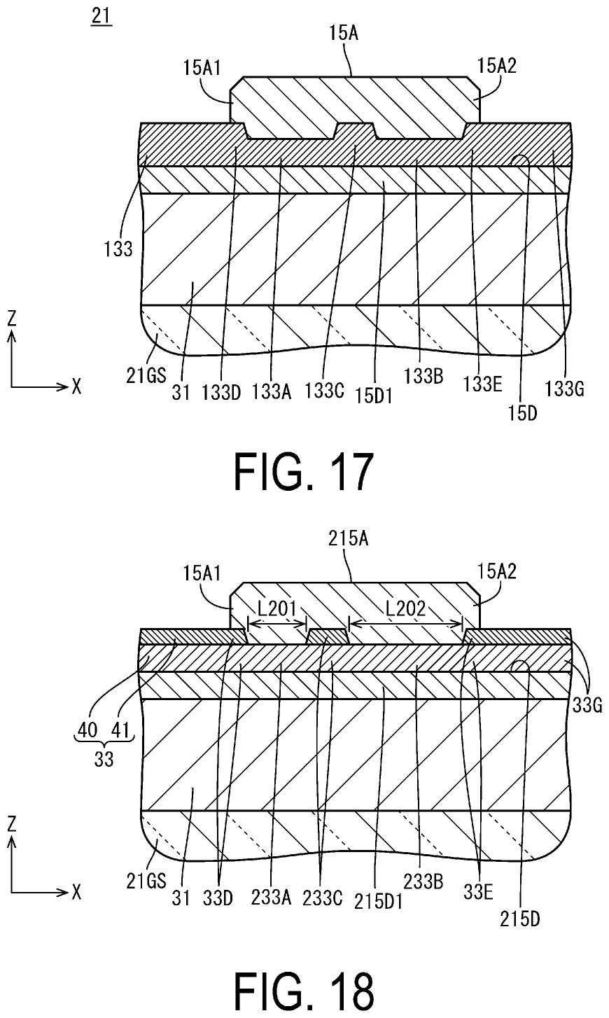

A second embodiment will now be described with reference to FIG. 17. In the second embodiment, a case where a configuration of a gate insulating film 133 is changed is described. Further, repetitive descriptions of structures, actions, and effects similar to those of the first embodiment described above will be omitted.

As shown in FIG. 17, the gate insulating film 133 according to this embodiment has a single-layer structure. The gate insulating film 133 is made of, for example, SiO₂. The gate insulating film 133 has a film thickness varying depending on a portion, has a film thickness of, for example, approximately 100 nm in a first thick portion 133A and a second thick portion 133B, and has a film thickness of, for example, approximately 150 nm in a third thick portion 133C, a fourth thick portion 133D, a fifth thick portion 133E, a sixth thick portion 33F, and a seventh thick portion 133G. In order to form such a gate insulating film 133, an etching processing time or the like is adjusted in a first etching step of a fourth step, and thus it is possible to control a depth to which a portion (see FIG. 11) exposed without being covered with a first resist film R1 is removed.

As described above, according to this embodiment, the gate insulating film 133 has a single-layer structure. Compared to a case where the gate insulating film has a layered structure including a plurality of insulating films, a film formation process required for manufacturing can be reduced.

### Third Embodiment

A third embodiment will be described with reference to FIG. 18. In the third embodiment, a case where configurations of a first thick portion 233A and a second thick portion 233B are changed from those in the first embodiment described above is described. Further, repetitive descriptions of structures, actions, and effects similar to those of the first embodiment described above will be omitted.

As shown in FIG. 18, the first thick portion 233A and the second thick portion 233B according to this embodiment have different dimensions L201 and L202 in the X-axis direction. First, the first thick portion 233A is located closer to a first source electrode 15B (see FIG. 4) in the X-axis direction than a third thick portion 233C, that is, located on the left side in FIG. 18. On the other hand, the second thick portion 233B is located closer to a first drain electrode 15C in the X-axis direction than the third thick portion 233C (see FIG. 4), that is, located on the right side in FIG. 18. The dimension L202 of the second thick portion 233B in the X-axis direction is larger than the dimension L201 of the first thick portion 233A in the X-axis direction.

Here, electric field concentration tends to occur more easily in the vicinity of the first drain electrode 15C connected to a signal supply target than in the other portions of a first semiconductor portion 215D. In particular, a high voltage is applied to a first TFT 15 belonging to a buffer circuit, resulting in a concern that the above-described electric field concentration may occur. In this regard, according to this embodiment, the second thick portion 233B located closer to the first drain electrode 15C in the X-axis direction than the third thick portion 233C has a larger dimension L202 in the X-axis direction than that of the first thick portion 233A located closer to the first source electrode 15B in the X-axis direction than the third thick portion 233C, thereby increasing the resistance of a portion overlapping the second thick portion 233B in a channel region 215D1 generated in the first semiconductor portion 215D. Thereby, electric field concentration is less likely to occur in the vicinity of the first drain electrode 15C in the first semiconductor portion 215D, and thus the occurrence of hot carrier injection is further suppressed.

As described above, according to this embodiment, the first source electrode 15B is connected to a signal supply source (driver 12 or flexible substrate 13) and receives a signal supplied from the signal supply source, whereas the first drain electrode 15C is connected to a signal supply target (gate wiring line 26) and is capable of supplying a signal to the signal supply target. The first thick portion 233A is located closer to the first source electrode 15B than the third thick portion 233C in the first direction, and the second thick portion 233B is located closer to the first drain electrode 15C than the third thick portion 233C in the first direction and has a larger dimension L202 in the first direction than that of the first thick portion 233A. When a voltage equal to or higher than a threshold voltage in the first TFT 15 is applied to the first gate electrode 215A, a signal supplied from the signal supply source to the first source electrode 15B is transmitted to the first drain electrode 15C via the channel region 215D1 generated in the first semiconductor portion 215D and is supplied from the first drain electrode 15C to the signal supply target. Here, electric field concentration tends to occur more easily in the vicinity of the first drain electrode 15C connected to the signal supply target than in the other portions of the first semiconductor portion 215D. In this regard, the second thick portion 233B located closer to the first drain electrode 15C in the first direction than the third thick portion 233C has a larger dimension L202 in the first direction than the first thick portion 233A located closer to the first source electrode 15B in the first direction than the third thick portion 233C, thereby increasing the resistance of a portion overlapping the second thick portion 233B in the channel region 215D1 generated in the first semiconductor portion 215D. Thereby, electric field concentration is less likely to occur in the vicinity of the first drain electrode 15C in the first semiconductor portion 215D, and thus the occurrence of hot carrier injection is further suppressed.

### Fourth Embodiment

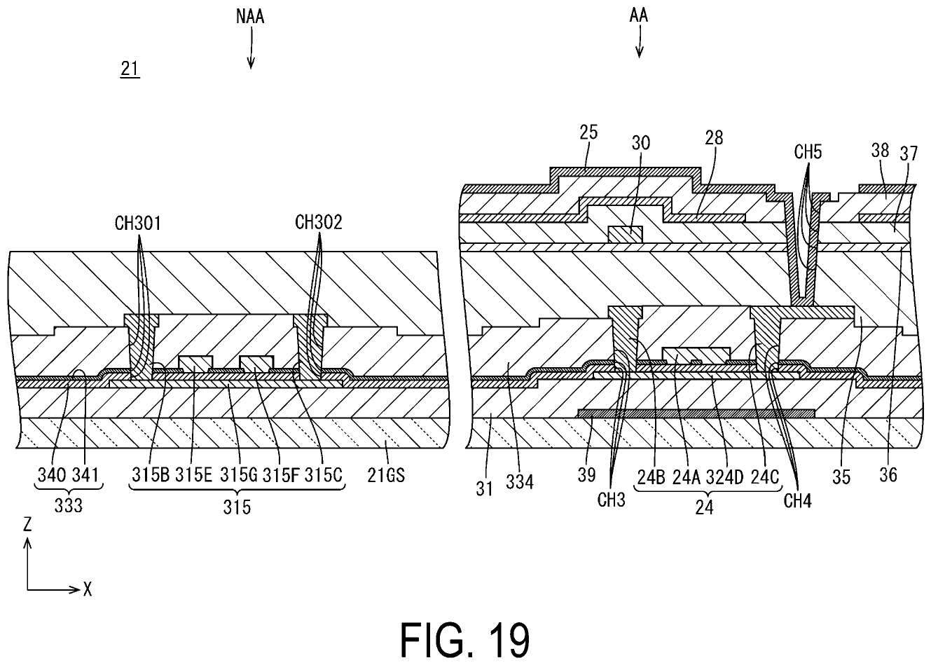

A fourth embodiment will be described with reference to FIGS. 19 to 31. In the fourth embodiment, a case where configurations of a first TFT 315 and a gate insulating film 333 are changed from those in the first embodiment described above is described. Further, repetitive descriptions of structures, actions, and effects similar to those of the first embodiment described above will be omitted.

As shown in FIG. 19, the first TFT 315 according to this embodiment includes two gate electrodes 315E and 315F instead of the single first gate electrode 15A (see FIG. 4) described in the first embodiment. The two gate electrodes 315E and 315F include a first gate electrode (first electrode) 315E and a third gate electrode (fourth electrode) 315F that are disposed spaced apart from each other in the X-axis direction (first direction). Among these, the first gate electrode 315E is disposed to be biased closer to the first source electrode 315B (on the left side in FIG. 19) than the center position in the first semiconductor portion 315G in the X-axis direction. The third gate electrode 315F is disposed to be biased closer to the first drain electrode 315C (on the right side in FIG. 19) than the center position in the first semiconductor portion 315G in the X-axis direction. Similar to the first embodiment, the first semiconductor portion 315G extends in the X-axis direction and has a substantially rectangular shape that is horizontally elongated in a plan view. In the first semiconductor portion 315G, a portion between the center position in the X-axis direction and a position connected to the first source electrode 315B (a position overlapping a first contact hole CH301) overlaps the first gate electrode 315E. In the first semiconductor portion 315G, a portion between the center position in the X-axis direction and a portion connected to the first drain electrode 315C (a portion overlapping a second contact holes CH302) overlaps the third gate electrode 315F.

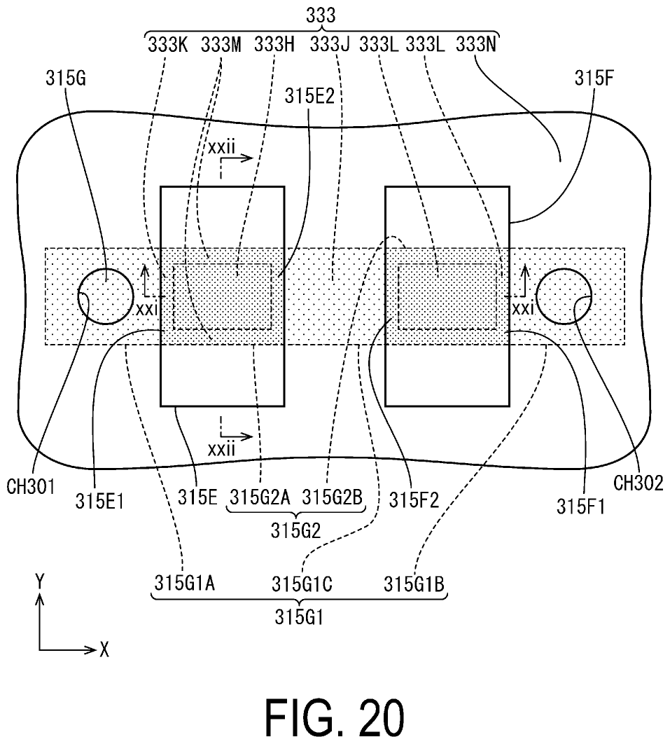

In this embodiment, a portion of a semiconductor film constituting the first semiconductor portion 315G described above is made conductive by ion implantation of a dopant (impurities) in a manufacturing process, whereby the first semiconductor portion 315G includes a conductive region 315G1 as shown in FIG. 20. A region of the first semiconductor portion 315G which is not made conductive is a non-conductive region. In the non-conductive region of the first semiconductor portion 315G, charges can move only under a specific condition (when a signal is supplied to the gate electrodes 315E and 315F). That is, the non-conductive region is a channel region 315G2. In FIG. 20, the conductive region 315G1 and the channel region 315G2 in the first semiconductor portion 315G are shown in different shaded shapes. The channel region 315G2 is a portion of the first semiconductor portion 315G which overlaps the gate electrodes 315E and 315F in a plan view. That is, two channel regions 315G2 are located at positions spaced apart from each other in the X-axis direction in the first semiconductor portion 315G. Specifically, the channel regions 315G2 include a first channel region 315G2A overlapping the first gate electrode 315E and a second channel region 315G2B overlapping the third gate electrode 315F. The conductive region 315G1 is a portion of the first semiconductor portion 315G which does not overlap the gate electrodes 315E and 315F in a plan view. The conductive region 315G1 has a lower resistivity than that of the non-conductive region and allows charges to move at all times, and thus the conductive region 315G1 functions as a conductor. The conductive processing for a semiconductor film is performed by providing a configuration (the gate electrodes 315E and 315F, and the like) constituted by a second metal film 332 and then using the configuration (the gate electrodes 315E and 315F, and the like) as a mask in a manufacturing process for an array substrate 21. Regarding the conductive processing, the conductive processing is selectively performed on a portion (non-overlapping portion, exposed portion) of the semiconductor film which is not covered with the structure constituted by the second metal film 332, and the conductive processing is not performed on a portion (overlapping portion, unexposed portion) covered with the structure constituted by the second metal film 332. The conductive region 315G1 includes a first conductive region (source region) 315G1A connected to the first source electrode 315B, a second conductive region (drain region) 315G1B connected to the first drain electrode 315C, and a third conductive region 315G1C interposed between the two channel regions 315G2. The first conductive region 315G1A partially overlaps the first contact hole CH301. The second conductive region 315G1B partially overlaps the second contact hole CH302.

As shown in FIG. 20, both the first gate electrode 315E and the third gate electrode 315F extend in the Y-axis direction and have a substantially rectangular shape that is vertically elongated in a plan view. The length dimensions (the dimensions in the Y-axis direction) of the first gate electrode 315E and the third gate electrode 315F are larger than the width dimension of the first semiconductor portion 315G, and the width dimensions thereof (the dimensions in the X-axis direction) are smaller than the length dimension (the dimension in the X-axis direction) of the first semiconductor portion 315G. Both the first gate electrode 315E and the third gate electrode 315F are disposed across the first semiconductor portion 315G so as to overlap the first semiconductor portion 315G over the entire width thereof. Both end portions of each of the first gate electrode 315E and the third gate electrode 315F in the length direction (Y-axis direction) are disposed not to overlap the first semiconductor portion 315G.

In this manner, as shown in FIG. 20, the first TFT 315 according to this embodiment has a double-gate (multi-gate) structure in which two gate electrodes 315E and 315F are disposed to overlap the first semiconductor portion 315G. According to the first TFT 315 having a double-gate structure as in this embodiment, hot carrier injection is less likely to occur even when a high voltage is applied. However, since the number of end portions of the gate electrodes 315E and 315F is larger in the first TFT 315 having a double-gate structure than in the first TFT 15 having a single-gate structure described in the first embodiment, ESD is more likely to occur between the end portions of the gate electrodes 315E and 315F and the first semiconductor portion 315G. For this reason, the end portions of the gate electrodes 315E and 315F and the first semiconductor portion 315G may be damaged due to the ESD, resulting in a concern that a yield may be deteriorated.

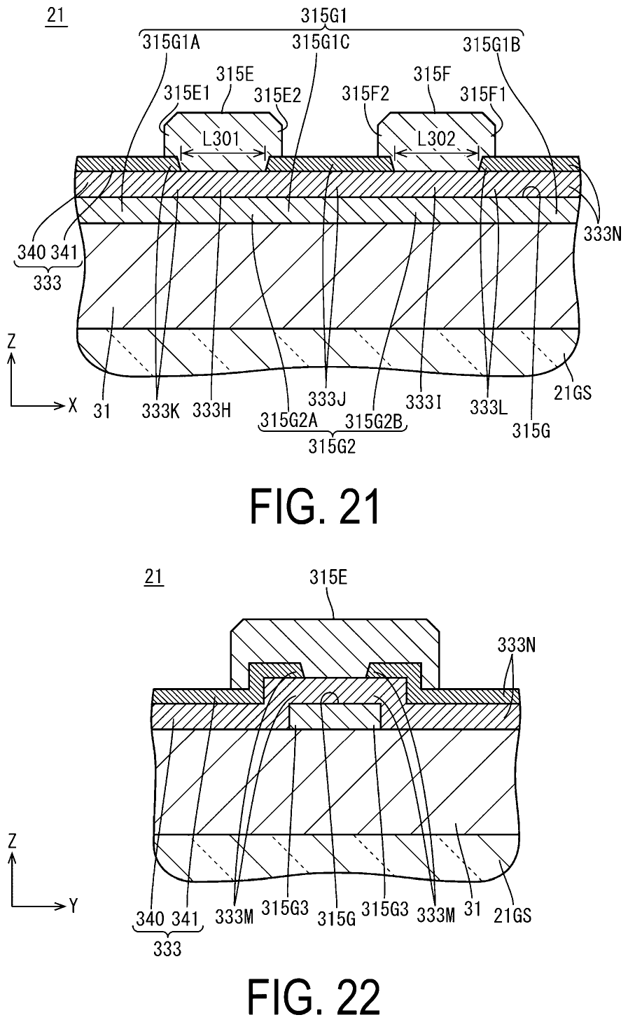

In this regard, in this embodiment, as shown in FIG. 21, the gate insulating film 333 interposed between the first and third gate electrodes 315E and 315F and the first semiconductor portion 315G has a configuration in which the film thicknesses thereof vary depending on their positions in the X-axis direction (first direction). That is, the gate insulating film 333 has a configuration in which a first thick portion 333H, a second thick portion 333I having the same film thickness as that of the first thick portion 333H, a third thick portion 333J having a film thickness larger than that of the first thick portion 333H, a fourth thick portion 333K having a film thickness larger than that of the first thick portion 333H, and a fifth thick portion 333L having a film thickness larger than that of the first thick portion 333H are lined up in the X-axis direction.

As shown in FIG. 21, the first thick portion 333H and the second thick portion 333I are disposed at positions spaced apart from each other in the X-axis direction (first direction). The first thick portion 333H overlaps both the first gate electrode 315E and the first semiconductor portion 315G, whereas the second thick portion 333I overlaps both the third gate electrode 315F and the first semiconductor portion 315G. Specifically, the first thick portion 333H is disposed to overlap a portion of the first semiconductor portion 315G and a center-side portion (a portion excluding both end portions 315E1 and 315E2) of the first gate electrode 315E in the X-axis direction. The second thick portion 333I is disposed to overlap a portion of the first semiconductor portion 315G and a center-side portion (a portion excluding both end portions 315F1 and 315F2) of the third gate electrode 315F in the X-axis direction. A dimension L301 of the first thick portion 333H in the X-axis direction and a dimension L302 of the second thick portion 333I in the X-axis direction are substantially equal to each other. The third thick portion 333J is disposed to be interposed between the first thick portion 333H and the second thick portion 333I in the X-axis direction. That is, a gap corresponding to the third thick portion 333J is provided between the first thick portion 333H and the second thick portion 333I. The third thick portion 333J is disposed to overlap a central portion of the first semiconductor portion 315G in the X-axis direction. The dimension of the third thick portion 333J in the X-axis direction is larger than the dimension of the third thick portion 33C (see FIG. 6) described in the first embodiment in the X-axis direction. For this reason, the sum of the dimensions of the first thick portion 333H, the second thick portion 333I, and the third thick portion 333J in the X-axis direction is larger than the sum of the dimensions of the first thick portion 33A, the second thick portion 33B, and the third thick portion 33C (see FIG. 6) described in the first embodiment in the X-axis direction. The fourth thick portion 333K is disposed at a position overlapping one end portion 315E1 (on the left side in FIG. 21) of the first gate electrode 315E in the X-axis direction. The fourth thick portion 333K is disposed to sandwich the first thick portion 333H with the third thick portion 333J in the X-axis direction. The fifth thick portion 333L is disposed at a position overlapping one end portion 315F1 (on the right side in FIG. 21) of the third gate electrode 315F in the X-axis direction. The fifth thick portion 333L is disposed to sandwich the second thick portion 333I with the third thick portion 333J in the X-axis direction. The third thick portion 333J is disposed to overlap both the other end portion 315E2 (on the right side in FIG. 21) of the first gate electrode 315E in the X-axis direction and the first semiconductor portion 315G and overlap both the other end portion 315F2 (on the left side in FIG. 21) of the third gate electrode 315F in the X-axis direction and the first semiconductor portion 315G.

In this embodiment, the film thickness of each of the first thick portion 333H and the second thick portion 333I is set to such a size that the channel region 315G2 is formed in each of the portions of the first semiconductor portion 315G which overlaps the first thick portion 333H and the second thick portion 333I when a predetermined voltage (a voltage equal to or higher than a threshold value) is applied to the first gate electrode 315E and the third gate electrodes 315F. That is, the voltages applied to the first gate electrode 315E and the third gate electrode 315F are set to such values that the channel region 315G2 is generated in portions of the first semiconductor portion 315G which overlap the first thick portion 333H and the second thick portions 333I having relatively small thicknesses. Thus, the channel regions 315G2A and 315G2B are generated in non-conductive regions which are portions of the first semiconductor portion 315G overlapping the first gate electrode 315E and the third gate electrode 315F, respectively.

According to such a configuration, when a predetermined voltage is applied to the first and third gate electrodes 315E and 315F, the channel region 315G2 is generated in the first semiconductor portion 315G. Accordingly, electrons move between the first source electrode 315B and the first drain electrode 315C via the channel region 315G2. Here, the gate insulating film 333 interposed between the first and third gate electrodes 315E and 315F and the first semiconductor portion 315G includes the first thick portion 333H, the second thick portion 333I having the same film thickness as that of the first thick portion 333H, the third thick portion 333J having a film thickness larger than that of the first thick portion 333H, the fourth thick portion 333K having a film thickness larger than that of the first thick portion 333H, and the fifth thick portion 333L having a film thickness larger than that of the first thick portion 333H. Among these, the third thick portion 333J is disposed to be interposed between the first thick portion 333H overlapping both the first gate electrode 315E and the first semiconductor portion 315G and the second thick portion 333I overlapping both the third gate electrode 315F and the first semiconductor portion 315G in the X-axis direction, and thus the resistance of the channel region 315G2 becomes higher than that in a single-gate structure of the related art, the occurrence of hot carrier injection is suppressed, and deterioration of transistor performance over time can be suppressed. In addition, the fourth thick portion 333K is disposed to overlap both the one end portion 315E1 of the first gate electrode 315E in the X-axis direction and the first semiconductor portion 315G, the fifth thick portion 333L is disposed to overlap both the one end portion 315F1 of the third gate electrode 315F in the X-axis direction and the first semiconductor portion 315G, and the third thick portion 333J is disposed to overlap both the other end portion 315E2 of the first gate electrode 315E in the X-axis direction and the first semiconductor portion 315G and overlap both the other end portion 315F2 of the third gate electrode 315F in the X-axis direction and the first semiconductor portion 315G, and thus ESD is less likely to occur between the first semiconductor portion 315G and the end portions 315E1, 315E2, 315F1, and 315F2 of the first gate electrode 315E and the third gate electrode 315F in the X-axis direction. Thereby, damage to the end portions 315E1, 315E2, 315F1, and 315F2 of the first gate electrode 315E and the third gate electrode 315F in the X-axis direction and the first semiconductor portion 315G due to the ESD is less likely to occur, thereby improving a yield. In addition, since the first thick portion 333H and the second thick portion 333I have the same dimension in the X-axis direction, and thus the lengths of the channel regions 315G2A and 315G2B generated in the first semiconductor portion 315G are equal to each other in the X-axis direction, and the resistances of the portions are equal to each other.

As shown in FIG. 21, the gate insulating film 333 has a layered structure of a lower insulating film 340 and an upper insulating film 341. The lower insulating film 340 is disposed on the upper layer side of the first semiconductor portion 315G. The lower insulating film 340 is made of, for example, SiO₂ and has a film thickness of, for example, approximately 100 nm. The upper insulating film 341 is located on the upper layer side of the lower insulating film 340, and is located on the lower layer side of the first gate electrode 315E. The material of the upper insulating film 341 is different from that of the lower insulating film 340. The film thickness of the upper insulating film 341 is smaller than that of the lower insulating film 340. The upper insulating film 341 is made of, for example, SiN and has a film thickness of, for example, approximately 50 nm. In this manner, the gate insulating film 333 has a layered structure of the lower insulating film 340 and the upper insulating film 341 made of different materials, and thus the first thick portion 333H, the second thick portion 333I, the third thick portion 333J, the fourth thick portion 333K, and the fifth thick portion 333L having different film thicknesses can be easily provided.

In this embodiment, the first thick portion 333H and the second thick portion 333I are constituted by the lower insulating film 340 as shown in FIG. 21. On the other hand, the third thick portion 333J, the fourth thick portion 333K, and the fifth thick portion 333L are constituted by the upper insulating film 341 and the lower insulating film 340. That is, the third thick portion 333J, the fourth thick portion 333K, and the fifth thick portion 333L have the same film thickness. According to such a configuration, in the manufacturing process, the lower insulating film 340 and the upper insulating film 341 are sequentially formed, and then the upper insulating film 341 is selectively removed, whereby it is possible to easily provide the first thick portion 333H and the second thick portion 333I constituted by the lower insulating film 340, and the third thick portion 333J, the fourth thick portion 333K, and the fifth thick portion 333L constituted by the lower insulating film 340 and the upper insulating film 341. In addition, the manufacturing is facilitated as compared to a case where the film thicknesses of the third thick portion 333J, the fourth thick portion 333K, and the fifth thick portion 333L are all different from each other.

In addition, as shown in FIG. 22, the gate insulating film 333 includes a sixth thick portion 333M having a film thickness larger than that of the first thick portion 333H. The sixth thick portion 333M is disposed to overlap an end portion 315G3 of the first semiconductor portion 315G in the Y-axis direction (the second direction intersecting the first direction). The sixth thick portion 333M has the same film thickness as those of the third thick portion 333J, the fourth thick portion 333K, and the fifth thick portion 333L. That is, the sixth thick portion 333M is constituted by the upper insulating film 341 and the lower insulating film 340, similar to the third thick portion 333J, the fourth thick portion 333K, and the fifth thick portion 333L.

In addition, as shown in FIGS. 21 and 22, the gate insulating film 333 includes a seventh thick portion 333N having a film thickness larger than that of the first thick portion 333H. The seventh thick portion 333N constitutes a portion of the gate insulating film 333 which does not overlap both the first gate electrode 315E and the first semiconductor portion 315G in a plan view. The seventh thick portion 333N has the same film thickness as those of the third thick portion 333J, the fourth thick portion 333K, the fifth thick portion 333L, and the sixth thick portion 333M. That is, the seventh thick portion 333N is constituted by the upper insulating film 341 and the lower insulating film 340, similar to the third thick portion 333J, the fourth thick portion 333K, the fifth thick portion 333L, and the sixth thick portion 333M.

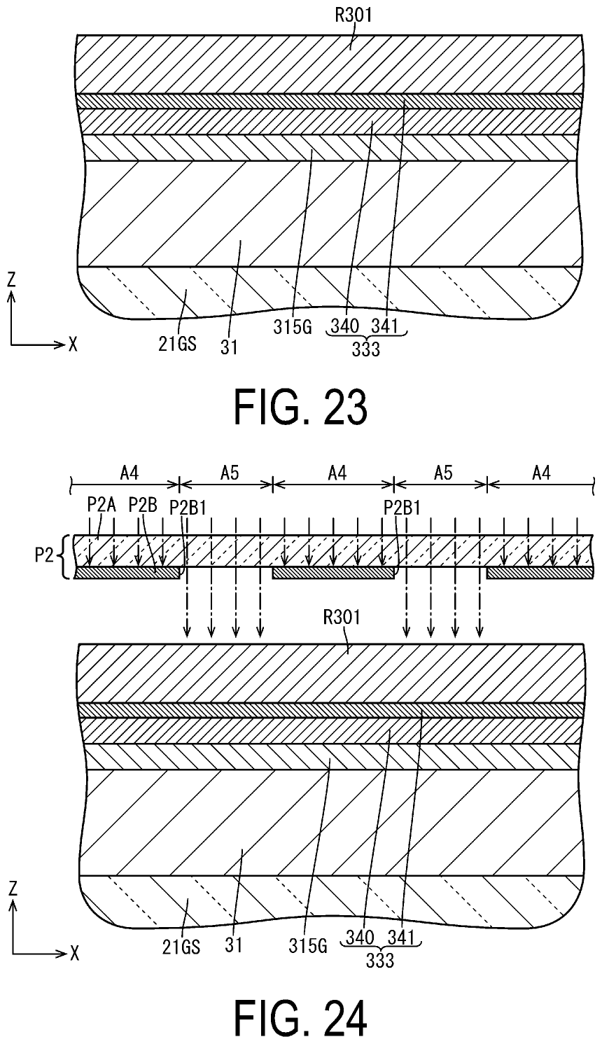

This embodiment has the above-described structure, and an array substrate manufacturing step included in the manufacturing method for the liquid crystal panel 11 will be subsequently described. The array substrate manufacturing step includes the first to fifteenth steps described in the first embodiment, and the fourth and fifth steps different from those in the first embodiment will be described below in detail with reference to FIGS. 23 to 31. FIGS. 23 to 31 show the same cross-sectional configuration as that in FIG. 21.

In the fourth step, as shown in FIG. 23, the lower insulating film 340 constituting the gate insulating film 333 is first formed in a solid state on the upper layer side of the first semiconductor portion 315G, then the upper insulating film 341 is formed in a solid state on the upper layer side of the lower insulating film 340, and then a first resist film R301 is formed in a solid state on the upper layer side of the upper insulating film 341. Thereafter, the first resist film R301 is exposed using an exposure device and a second photomask P2 shown in FIG. 24 (first exposure step). The first resist film R301 used in the fourth step is made of a positive photosensitive material. Here, the second photomask P2 will be described. As shown in FIG. 24, the second photomask P2 includes a transparent second base material P2A having a sufficiently high light transmittance, and a second light shielding film P2B formed on the main surface of the second base material P2A. The second light shielding film P2B blocks exposure light from a light source of the exposure device, and the transmittance of the exposure light is approximately 0%. The second light shielding film P2B has a partial opening P2B1. The opening P2B1 has a size equal to or larger than the resolution of the exposure device, and can transmit light in its formation range.

As shown in FIG. 24, the second light shielding film P2B has a configuration in which two openings P2B1 are disposed in each of island-shaped areas overlapping formation positions for the first semiconductor portions 315G to be formed in a non-display region NAA, and one opening P2B1 is disposed in each of island-shaped areas overlapping formation positions for the second semiconductor portions 324D to be formed in a display region AA. Specifically, the opening P2B1 is disposed in areas overlapping formation positions for the first thick portion 333H and the second thick portion 333I to be formed of the gate insulating film 333. On the other hand, in the non-display region NAA, the second light shielding film P2B is disposed in an area where an opening edge portion of the opening P2B1 overlaps formation positions for the third thick portion 333J to be formed, the fourth thick portion 333K, the fifth thick portion 333L, and the sixth thick portion 333M of the gate insulating film 333, and is disposed in an area where portions other than the opening edge portion of the opening P2B1 overlap a formation position for the seventh thick portion 333N to be formed.

As shown in FIG. 24, in the second photomask P2, an area in which the second light shielding film P2B is formed is a second light shielding region A4 in which light is blocked. The transmittance of light in the second light shielding region A4 is approximately 0%. In the second photomask P2, an area in which the opening P2B1 is formed is a second transmissive region A5 in which light is transmitted. Two second transmissive regions A5 are disposed at positions spaced apart from each other in the Y-axis direction (positions that overlap the formation positions for the first thick portion 333H and the second thick portion 333I to be formed) at formation positions for the first semiconductor portions 315G to be formed. The transmittance of light in the second transmissive region A5 is approximately 100%. The second light shielding region A4 and the second transmissive region A5 constitute an exposure pattern in the second photomask P2.

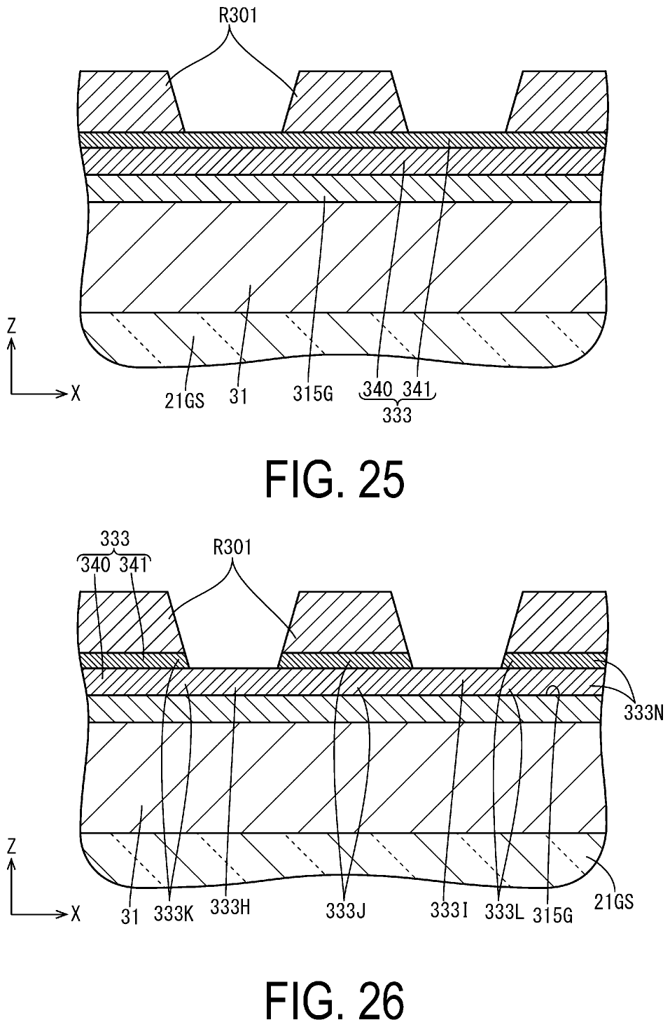

In the fourth step, the first resist film R301 is irradiated with exposure light emitted from the light source of the exposure device through the second photomask P2 having the above-described configuration. As shown in FIG. 24, the amount of exposure of the first resist film R301 is different for each portion overlapping each of the regions A4 and A5 of the second photomask P2. That is, in the first resist film R301, the portion overlapping the second light shielding region A4 is hardly exposed and is left unexposed, and the portion overlapping the second transmissive region A5 is sufficiently exposed. The first resist film R301 used in the fourth step is made of a positive photosensitive material. Thus, when the first resist film R301 is developed after the exposure (first development step), as shown in FIG. 25, the light exposed portion (the portion overlapping the second transmissive region A5) of the first resist film R301 is removed, and the light unexposed portion (the portion overlapping the second light shielding region A4) remains. In this manner, in the first resist film R301, portions overlapping the second light shielding region A4 in the second photomask P2 selectively remain.

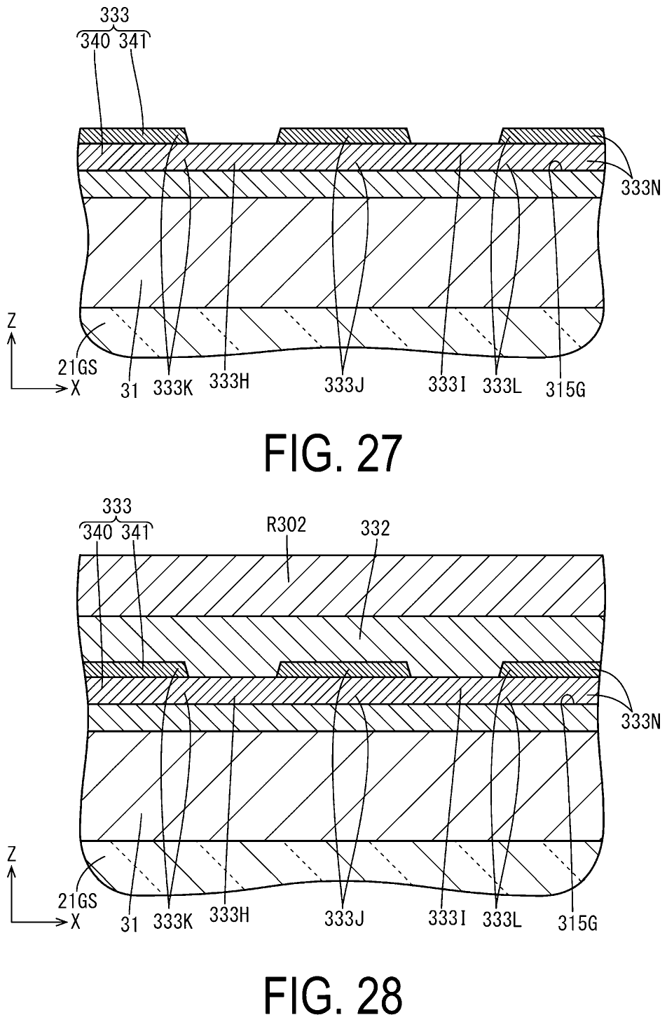

The gate insulating film 333 is etched using the first resist film R301, which is developed in this manner, as a mask (first etching step). In this etching, etching conditions (such as the type of etching gas in the case of dry etching, and the type of etching solution in the case of wet etching) are set such that an etching rate for the upper insulating film 341 constituting the gate insulating film 333 is high and an etching rate for the lower insulating film 340 is low. When the first etching step is performed, as shown in FIG. 26, in the upper insulating film 341 constituting the gate insulating film 333, a portion that is exposed without being covered with the first resist film R301 (an area overlapping the second transmissive region A5 of the second photomask P2) is selectively removed, but a portion that is covered with the first resist film R301 (an area overlapping the second light shielding region A4 of the second photomask P2) remains unremoved. The lower insulating film 340 constituting the gate insulating film 333 is not entirely removed, inclusive of an area overlapping the second transmissive region A5. Thereby, in the gate insulating film 333, it is possible to easily provide the first thick portion 333H and the second thick portion 333I which are located in areas overlapping the second transmissive region A5 of the second photomask P2 and constituted by the lower insulating film 340, the third thick portion 333J located in an area overlapping the semi-transmissive region A3 and constituted by the lower insulating film 340 and the upper insulating film 341, and the fourth thick portion 333K, the fifth thick portion 333L, the sixth thick portion 333M, and the seventh thick portion 333N which are located in an area overlapping the second light shielding region A4 and are all constituted by the lower insulating film 340 and the upper insulating film 341. When the etching is terminated, the first resist film R301 is removed by ashing (first ashing step), as shown in FIG. 27.

After the fourth step is performed as described above, the fifth step is performed. In the fifth step, as shown in FIG. 28, the second metal film 332 is formed in a solid state on the upper layer side of the gate insulating film 333, and then the second resist film R302 is formed in a solid state on the upper layer side of the second metal film 332. The second resist film R302 used in the fifth step is made of a negative photosensitive material. Then, the second resist film R302 is exposed using an exposure device and the second photomask P2 (second exposure step). The second photomask P2 used in the second exposure step of the fifth step has the same exposure pattern (the second light shielding region A4 and the second transmissive region A5) as that of the second photomask P2 used in the first exposure step of the fourth step. In this manner, the second photomask P2 having the same exposure pattern can be used in the first exposure step of exposing the first resist film R301 and the second exposure step of exposing the second resist film R302, which is suitable for reducing costs associated with the equipment required for manufacturing.

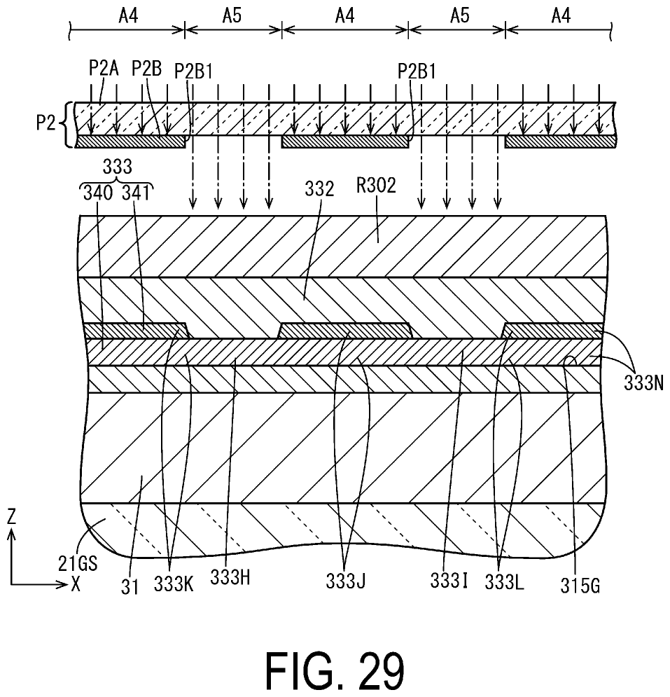

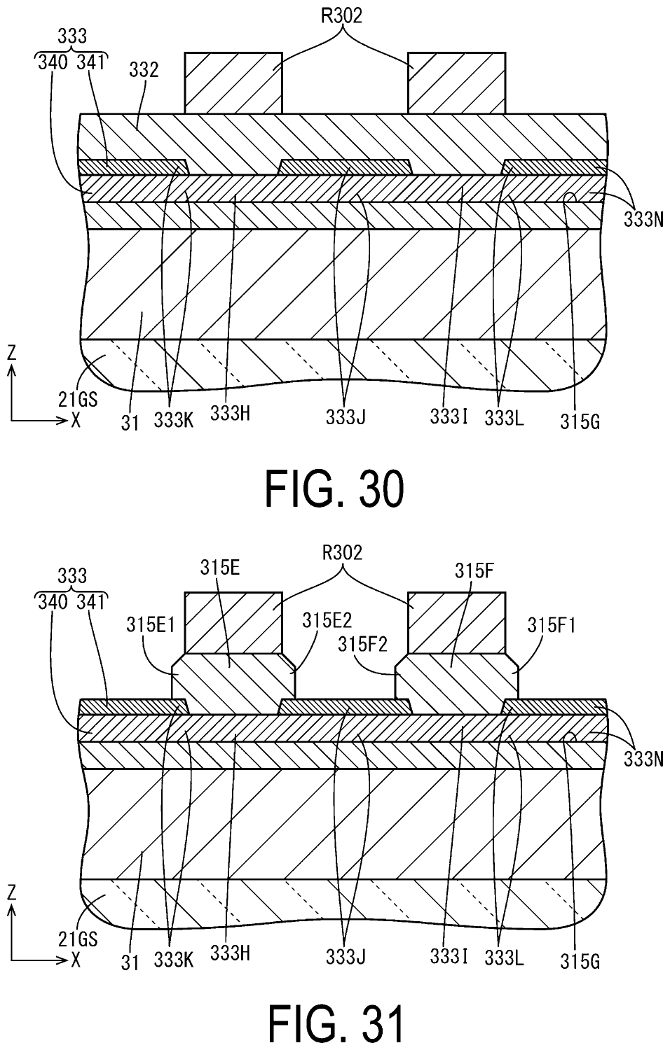

In the fifth step, the second resist film R302 is irradiated with exposure light emitted from the light source of the exposure device through the second photomask P2 having the same exposure pattern as the second photomask P2 used in the first exposure step of the fourth step. As shown in FIG. 29, the amount of exposure of the second resist film R302 is different for each portion overlapping each of the regions A4 and A5 of the second photomask P2. That is, in the second resist film R302, the portion overlapping the second light shielding region A4 is hardly exposed, and the portion overlapping the second transmissive region A5 is sufficiently exposed. The second resist film R302 used in the fifth step is made of a negative photosensitive material. Thus, when the second resist film R302 is developed after the exposure (second development step), as shown in FIG. 30, the light unexposed portion (the portion overlapping the second light shielding region A4) of the second resist film R302 is removed, and the light exposed portion (the portion overlapping the second transmissive region A5) remains. In this manner, in the second resist film R302, a portion overlapping the second transmissive region A5 in the second photomask P2 selectively remains.

When second metal film 332 is etched using the second resist film R302, which is developed in this manner, as a mask (second etching step), the first gate electrode 315E located in an area overlapping the second transmissive regions A5 of the second photomask P2 is provided as shown in FIG. 31. The first gate electrode 315E provided through the second etching step is disposed such that both the end portions 315E1 and 315E2 overlap the fourth thick portion 333K and the fifth thick portion 333L of the gate insulating film 333 in the X-axis direction, and the center-side portion between both the end portions 315E1 and 315E2 overlaps the first thick portion 333H, the second thick portion 333I, and the third thick portion 333J of the gate insulating film 333. When the etching is terminated, the second resist film R302 is removed by ashing as shown in FIG. 21 (second ashing step). In the fifth step, the conductive processing for a semiconductor film is performed using a configuration (each gate electrode 315E, 315F or the like), which is constituted by the second metal film 332 patterned as described above, as a mask. When the conductive processing is performed, a dopant is selectively ion-implanted into a portion of the semiconductor film which is not covered with the structure constituted by the second metal film 332, and the dopant is not ion-implanted into a portion of the semiconductor film which is covered with the structure constituted by the second metal film 332. Thereby, the conductive regions 315G1 (the first conductive region 315G1A, the second conductive region 315G1B, and the third conductive region 315G1C) are generated in the semiconductor film. When the sixth step is performed after the fifth step is terminated in this manner, a first interlayer insulating film 334 is formed on the upper layer side of the first gate electrode 315E and then patterned (see FIG. 19).

As described above, the first TFT 315 according to this embodiment includes the first semiconductor portion 315G extending in the first direction and made of a semiconductor material, the first gate electrode (first electrode) 315E disposed to overlap a portion of the first semiconductor portion 315G, the third gate electrode (fourth electrode) 315F overlapping a portion of the first semiconductor portion 315G and disposed at a position spaced apart from the first gate electrode 315E in the first direction, the gate insulating film 333 interposed between the first and third gate electrodes 315E and 315F and the first semiconductor portion 315G, the first source electrode 315B disposed to overlap a portion of the first semiconductor portion 315G and connected to the first semiconductor portion 315G, and the first drain electrode 315C disposed to overlap a portion of the first semiconductor portion 315G at a position spaced apart from a connection position between the first source electrode 315B and the first semiconductor portion 315G in the first direction and connected to the first semiconductor portion 315G. The gate insulating film 333 includes the first thick portion 333H, the second thick portion 333I having the same film thickness as that of the first thick portion 333H, the third thick portion 333J having a film thickness larger than that of the first thick portion 333H, the fourth thick portion 333K having a film thickness larger than that of the first thick portion 333H, and the fifth thick portion 333L having a film thickness larger than that of the first thick portion 333H. The first thick portion 333H is disposed at a position overlapping both the first gate electrode 315E and the first semiconductor portion 315G, the second thick portion 333I is disposed at a position overlapping both the third gate electrode 315F and the first semiconductor portion 315G, the third thick portion 333J is disposed to be interposed between the first thick portion 333H and the second thick portion 333I in the first direction, the fourth thick portion 333K overlaps both one end portion 315E1 of the first gate electrode 315E in the first direction and the first semiconductor portion 315G and is disposed to sandwich the first thick portion 333H with the third thick portion 333J, the fifth thick portion 333L overlaps both one end portion 315F1 of the third gate electrode 315F in the first direction and the first semiconductor portion 315G and is disposed to sandwich the second thick portion 333I with the third thick portion 333J, and the third thick portion 333J overlaps both the other end portion 315E2 of the first gate electrode 315E in the first direction and the first semiconductor portion 315G and is arranged to overlap both the other end portion 315F2 of the third gate electrode 315F in the first direction and the first semiconductor portion 315G.

When a voltage equal to or higher than a threshold voltage in the first TFT 315 is applied to the first gate electrode 315E, the channel region 315G2 is generated in the first semiconductor portion 315G. Accordingly, electrons move between the first source electrode 315B and the first drain electrode 315C via the channel region 315G2. Here, the gate insulating film 333 interposed between the first and third gate electrodes 315E and 315F and the first semiconductor portion 315G includes the first thick portion 333H, the second thick portion 333I having the same film thickness as that of the first thick portion 333H, the third thick portion 333J having a film thickness larger than that of the first thick portion 333H, the fourth thick portion 333K having a film thickness larger than that of the first thick portion 333H, and the fifth thick portion 333L having a film thickness larger than that of the first thick portion 333H. Among these, the third thick portion 333J is disposed to be interposed between the first thick portion 333H, which overlaps both the first gate electrode 315E and the first semiconductor portion 315G, and the second thick portion 333I, which overlaps both the third gate electrode 315F and the first semiconductor portion 315G, in the first direction, and thus the resistance of the channel region 315G2 becomes higher than that in a single-gate structure of the related art, the occurrence of hot carrier injection is suppressed, and deterioration of transistor performance over time can be suppressed. In addition, the fourth thick portion 333K is disposed to overlap both the one end portion 315E1 of the first gate electrode 315E in the first direction and the first semiconductor portion 315G, the fifth thick portion 333L is disposed to overlap both the one end portion 315F1 of the third gate electrode 315F in the first direction and the first semiconductor portion 315G, and the third thick portion 333J is disposed to overlap both the other end portion 315E2 of the first gate electrode 315E in the first direction and the first semiconductor portion 315G and overlap both the other end portion 315F2 of the third gate electrode 315F in the first direction and the first semiconductor portion 315G, and thus ESD is less likely to occur between the first semiconductor portion 315G and the end portions 315E1, 315E2, 315F1, and 315F2 of the first gate electrode 315E and the third gate electrode 315F in the first direction. Thereby, damage to the end portions 315E1, 315E2, 315F1, and 315F2 of the first gate electrode 315E and the third gate electrode 315F in the first direction or the first semiconductor portion 315G due to the ESD is less likely to occur, thereby improving a yield.

Further, a manufacturing method for the first TFT 315 according to this embodiment includes forming a semiconductor film made of a semiconductor material; patterning the semiconductor film to provide the first semiconductor portion 315G extending in the first direction; forming the gate insulating film 333 on the upper layer side of the first semiconductor portion 315G; forming the first resist film R301 made of a photosensitive material on the upper layer side of the gate insulating film 333; exposing and developing the first resist film R301; etching the gate insulating film 333 using the first resist film R301 as a mask to provide the first thick portion 333H disposed to overlap the first semiconductor portion 315G, the second thick portion 333I overlapping the first semiconductor portion 315G, disposed at a position spaced apart from the first thick portion 333H in the first direction, and having the same film thickness as that of the first thick portion 333H, the third thick portion 333J disposed to be interposed between the first thick portion 333H and the second thick portion 333I in the first direction at a position overlapping the first semiconductor portion 315G and having a film thickness larger than that of the first thick portion 333H, the fourth thick portion 333K overlapping the first semiconductor portion 315G, disposed to sandwich the first thick portion 333H with the third thick portion 333J in the first direction, and having a film thickness larger than that of the first thick portion 333H, and the fifth thick portion 333L overlapping the first semiconductor portion 315G, disposed to sandwich the second thick portion 333I with the third thick portion 333J in the first direction, and having a film thickness larger than that of the first thick portion 333H; forming the second metal film 332 on the upper layer side of the gate insulating film 333; forming the second resist film R302 made of a photosensitive material on the upper layer side of the second metal film 332; exposing and developing the second resist film R302; etching the second metal film 332 using the second resist film R302 as a mask to provide the first gate electrode 315E in which one end portion 315E1 in the first direction overlaps the fourth thick portion 333K, the other end portion 315E2 in the first direction overlaps the third thick portion 333J, and a portion between both the end portions 315E1 and 315E2 in the first direction overlaps the first thick portion 333H, and the third gate electrode 315F in which one end portion 315F1 in the first direction overlaps the fifth thick portion 333L, the other end portion 315F2 in the first direction overlaps the third thick portion 333J, and a portion between both the end portions 315F1 and 315F2 in the first direction overlaps the second thick portion 333I; forming the third metal film (second conductive film) on the upper layer side of the first gate electrode 315E; and patterning the third metal film to provide the first source electrode 315B disposed to overlap a portion of the first semiconductor portion 315G and connected to the first semiconductor portion 315G, and the first drain electrode 315C disposed to overlap a portion of the first semiconductor portion 315G at a position spaced apart from a connection position between the first source electrode 315B and the first semiconductor portion 315G in the first direction and connected to the first semiconductor portion 315G.

The first semiconductor portion 315G is provided by forming and patterning a semiconductor film. After the gate insulating film 333 and the first resist film R301 are sequentially formed on the upper layer side of the first semiconductor portion 315G, the first resist film R301 is exposed and developed. When the gate insulating film 333 is etched through the patterned first resist film R301, the first thick portion 333H, the second thick portion 333I, the third thick portion 333J, the fourth thick portion 333K, and the fifth thick portion 333L are provided. After the second metal film 332 and the second resist film R302 are sequentially formed on the upper layer side of the gate insulating film 333, the second resist film R302 is exposed and developed. When the second metal film 332 is etched through the patterned second resist film R302, the first gate electrode 315E is provided. The first source electrode 315B and the first drain electrode 315C are provided by forming and patterning the third metal film on the upper layer side of the first gate electrode 315E.

When a voltage equal to or greater than a threshold voltage of the first TFT 315 manufactured in this manner is applied to the first gate electrode 315E, the channel region 315G2 is generated in the first semiconductor portion 315G. Accordingly, electrons move between the first source electrode 315B and the first drain electrode 315C via the channel region 315G2. Here, the gate insulating film 333 interposed between the first gate electrode 315E and the first semiconductor portion 315G includes the first thick portion 333H, the second thick portion 333I having the same film thickness as that of the first thick portion 333H, the third thick portion 333J having a film thickness larger than that of the first thick portion 333H, the fourth thick portion 333K having a film thickness larger than that of the first thick portion 333H, and the fifth thick portion 333L having a film thickness larger than that of the first thick portion 333H. Among these, the third thick portion 333J is disposed to be interposed between the first thick portion 333H overlapping both the first gate electrode 315E and the first semiconductor portion 315G and the second thick portion 333I overlapping both the third gate electrode 315F and the first semiconductor portion 315G in the first direction, and thus the resistance of the channel region 315G2 becomes higher than that in a single-gate structure of the related art, the occurrence of hot carrier injection is suppressed, and deterioration of transistor performance over time can be suppressed. In addition, the fourth thick portion 333K is disposed to overlap both the one end portion 315E1 of the first gate electrode 315E in the first direction and the first semiconductor portion 315G, the fifth thick portion 333L is disposed to overlap both the one end portion 315F1 of the third gate electrode 315F in the first direction and the first semiconductor portion 315G, and the third thick portion 333J is disposed to overlap both the other end portion 315E2 of the first gate electrode 315E in the first direction and the first semiconductor portion 315G and overlap both the other end portion 315F2 of the third gate electrode 315F in the first direction and the first semiconductor portion 315G, and thus ESD is less likely to occur between the first semiconductor portion 315G and the end portions 315E1, 315E2, 315F1, and 315F2 of the first gate electrode 315E and the third gate electrode 315F in the first direction. Thereby, damage to the end portions 315E1, 315E2, 315F1, and 315F2 of the first gate electrode 315E and the third gate electrode 315F in the first direction or the first semiconductor portion 315G, due to the ESD is less likely to occur, thereby improving a yield.

In addition, the first resist film R301 made of a positive photosensitive material is formed on the upper layer side of the gate insulating film 333, the first resist film R301 is exposed and then developed through the second photomask P2 having the second light shielding region A4 disposed to overlap the formation areas for the third thick portion 333J to be formed, the fourth thick portion 333K, and the fifth thick portion 333L and blocking light and the second transmissive region A5 overlapping the formation areas for the first thick portion 333H and the second thick portion 333I to be formed and transmitting light, the second resist film R302 made of a negative photosensitive material is formed on the upper layer side of the second metal film 332, and the second resist film R302 is exposed and then developed through the second photomask P2.

The first resist film R301 formed on the upper layer side of the gate insulating film 333 is exposed through the second photomask P2. The amount of exposure of the first resist film R301 is different for each portion overlapping each region of the second photomask P2. That is, in the first resist film R301, a portion overlapping the second light shielding region A4 is hardly exposed, and a portion overlapping the second transmissive region A5 is sufficiently exposed. The first resist film R301 is made of a positive photosensitive material, and thus, when the first resist film R301 is developed, the light exposed portion (the portion overlapping the second transmissive region A5) is removed, and the light unexposed portion (the portion overlapping the second light shielding region A4) remains. The gate insulating film 333 is etched using the developed first resist film R301 as a mask, thereby providing the first thick portion 333H and the second thick portion 333I located in an area overlapping the second transmissive region A5 of the second photomask P2, and the third thick portion 333J, the fourth thick portion 333K, and the fifth thick portion 333L located in an area overlapping the second light shielding region A4.

The second resist film R302 formed on the upper layer side of the second metal film 332 is exposed through the second photomask P2 having the same exposure pattern as the second photomask P2 used when the first resist film R301 is exposed. The amount of exposure of the second resist film R302 is different for each portion overlapping each region of the second photomask P2. That is, in the second resist film R302, a portion overlapping the second light shielding region A4 is hardly exposed, and a portion overlapping the second transmissive region A5 is sufficiently exposed. The second resist film R302 is made of a negative photosensitive material, and thus, when the second resist film R302 is developed, the light unexposed portion (the portion overlapping the second light shielding region A4) is removed, and the light exposed portion (the portion overlapping the second transmissive region A5) remains. The second metal film 332 is etched using the developed second resist film R302 as a mask, thereby providing the first gate electrode 315E and the third gate electrode 315F in an area overlapping the second transmissive region A5 of the second photomask P2.

As described above, the second photomask P2 having the same exposure pattern can be used in the step of exposing the first resist film R301 and the step of exposing the second resist film R302, which is suitable for reducing costs associated with the equipment required for manufacturing.

### Fifth Embodiment

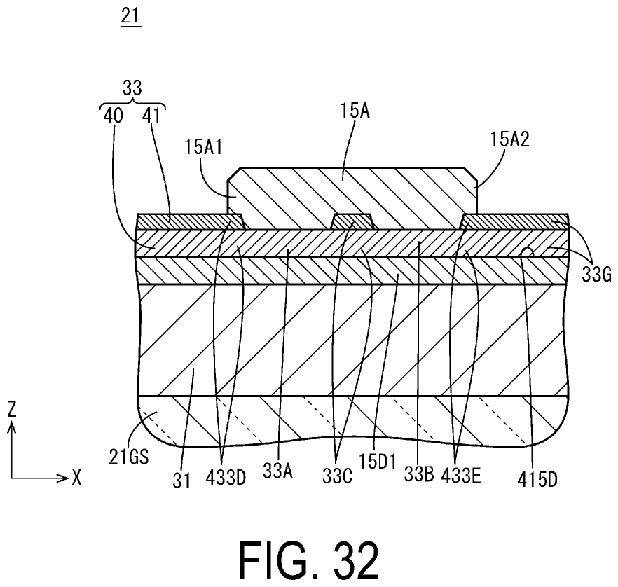

A fifth embodiment will now be described with reference to FIG. 32. In the fifth embodiment, a case where a configuration of a semiconductor film is changed from that in the first embodiment described above is described. Further, repetitive descriptions of structures, actions, and effects similar to those of the first embodiment described above will be omitted.

As shown in FIG. 32, an oxide-semiconductor material is used as a semiconductor material for the semiconductor film constituting a first semiconductor portion 415D according to this embodiment. The oxide semiconductor material used for the semiconductor film may include, for example, at least one metal element of In, Ga, and Zn, and may be, for example, an In—Ga—Zn—O-based semiconductor (for example, indium gallium zinc oxide). Here, the In—Ga—Zn—O-based semiconductor is a ternary oxide of In (indium), Ga (gallium), and Zn (zinc), there is no particular limitation on a ratio (composition ratio) of In, Ga, and Zn, and examples of the ratio include In:Ga:Zn=2:2:1, In:Ga:Zn=1:1:1, In:Ga:Zn=1:1:2, and the like. The In—Ga—Zn—O-based semiconductor used for the semiconductor film may be amorphous or crystalline. The semiconductor film may include other oxide semiconductors instead of In Reference Number: 23X00919, Japanese Patent Application No. 2023-178700 (Proof) Submission Date: Oct. 17, 2023, 31Ga—Zn—O-based semiconductor. The semiconductor film may include, for example, an In—Sn—Zn—O-based semiconductor (for example, In₂O₃—SnO₂—ZnO; InSnZnO). The In—Sn—Zn—O-based semiconductor is a ternary oxide of In (indium), Sn (tin), and Zn (zinc). Alternatively, the semiconductor film may include an In—W—Zn—O-based semiconductor including W (tungsten), an In—W—Sn—Zn—O-based semiconductor, an In—Al—Zn—O-based semiconductor, an In—Al—Sn—Zn—O-based semiconductor, a Zn—O-based semiconductor, an In—Zn—O-based semiconductor, a Zn—Ti—O-based semiconductor, a Cd—Ge—O-based semiconductor, a Cd—Pb—O-based semiconductor, CdO (cadmium oxide), a Mg—Zn—O-based semiconductor, an In—Ga—Sn—O-based semiconductor, an In—Ga—O-based semiconductor, a Zr—In—Zn—O-based semiconductor, a Hf—In—Zn—O-based semiconductor, an Al—Ga—Zn—O-based semiconductor, a Ga—Zn—O-based semiconductor, an In—Ga—Zn—Sn—O-based semiconductor, and the like. The oxide semiconductor material of the semiconductor film has a higher resistance value in a state where no voltage is applied (OFF state) than that of a polysilicon semiconductor material. Further, the oxide semiconductor material of the semiconductor film has higher electron mobility than that of an amorphous silicon semiconductor material.

As described above, according to this embodiment, an oxide-semiconductor material is used as the semiconductor material for the first semiconductor portion 415D. In the first semiconductor portion 415D made of an oxide-semiconductor material, portions that overlap a fourth thick portion 433D and a fifth thick portion 433E are likely to locally have high resistance due to an oxidation reduction effect. Thereby, electric field concentration is less likely to occur in the vicinity of the first source electrode 15B and the vicinity of the first drain electrode 15C in the first semiconductor portion 415D, and thus the occurrence of hot carrier injection is further suppressed.

### OTHER EMBODIMENTS

The technology described in the present specification is not limited to the embodiments described above and shown in the drawings, and the following embodiments, for example, are also included within the technical scope.

(1) The gate insulating films 33, 133, and 333 may have an eighth thick portion disposed at a position spaced apart from each of the second thick portions 33B, 133B, 233B, and 333I on a side opposite to each of the first thick portions 33A, 133A, 233A, and 333H in the X-axis direction and having the same film thickness as those of the first thick portions 33A, 133A, 233A, and 333H, and a ninth thick portion interposed between each of the second thick portions 33B, 133B, 233B, and 333I and the eighth thick portion in the X-axis direction and having a film thickness larger than those of the first thick portions 33A, 133A, 233A, and 333H.

(2) In the configurations described in the first, third, fourth, and fifth embodiments, the first thick portions 33A, 233A, and 333H and the second thick portions 33B, 233B, and 333I may partially include the upper insulating films 41 and 341 in addition to the lower insulating films 40 and 340. That is, when etching is performed in the fourth step, portions on the upper layer sides of the upper insulating films 41 and 341 may be removed, and portions on the lower layer sides of the upper insulating films 41 and 341 may be left.

(3) In the configuration described in the third embodiment, a ratio between the dimension L201 of the first thick portion 233A in the X-axis direction and the dimension L202 of the second thick portion 233B in the X-axis direction can be appropriately changed to values other than those shown in the drawings.

(4) In the configuration described in the fourth embodiment, the arrangement of the first gate electrode 315E and the third gate electrode 315F in the X-axis direction may be reversed.

(5) In the configuration described in the fourth embodiment, in the fifth step included in the array substrate manufacturing step, it is also possible to use a resist mask to control an area (the conductive region 315G1) where a dopant is ion-implanted when a conductive processing for a semiconductor film is performed. In this case, in the semiconductor film, portions overlapping the gate electrodes 315E and 315F can be set to be the conductive region 315G1, and portions not overlapping the gate electrode 315E and 315F can be set to be non-conductive regions. That is, the degree of freedom in design related to the formation regions for the conductive region 315G1 and the non-conductive regions is increased.

(6) In the configuration described in the fourth embodiment, the semiconductor film may not be subjected to the conductive processing. In this case, electrodes connected to both the portions (channel region 315G2) of the semiconductor film that overlap the gate electrode 315E and 315F may be provided.

(7) The configuration described in the second embodiment may be combined with the configurations described in the third to fifth embodiments.

(8) The configuration described in the third embodiment may be combined with the configurations described in the fourth and fifth embodiments.

(9) The configuration described in the fourth embodiment may be combined with the configuration described in the fifth embodiment.

(10) Specific materials used for each film provided on the array substrate 21 and specific numerical values of film thicknesses of the respective films can be appropriately changed to those not mentioned above.

(11) The first gate electrodes 15A, 215A, and 315E and the third gate electrode 315F may be configured to intersect the first semiconductor portions 15D, 215D, 315G, and 415D at an angle other than 90°.

(12) Specific planar shapes of the first semiconductor portions 15D, 215D, 315G, and 415D can be appropriately changed to shapes other than those shown in the drawings. Each of the first semiconductor portions 15D, 215D, 315G, and 415D may be bent in the middle as long as it includes a portion extending in the X-axis direction. In addition, specific planar shapes of the first gate electrode 15A, 215A, and 315E and the third gate electrode 315F can be appropriately changed to shapes other than those shown in the drawings.

(13) In the configurations described in the first to third, and fifth embodiments, in each of the exposure steps included in the fourth step and the fifth step, a gray-tone mask can also be used as the first photomask P1 in addition to a half-tone mask.

(14) Exposure patterns of the photomasks used in the fourth step and the fifth step may also be made different from each other.

(15) Instead of the driver 12, a source shared driving (SSD) circuit or the like may be monolithically provided on the array substrate 21. In this case, the circuit elements of the SSD circuit may also include the first TFTs 15 and 315.

(16) The driver 12 may be attached to the flexible substrate 13.

(17) A gate driver may be attached to the array substrate 21 instead of the circuit portion 14.

(18) The order of stacking the semiconductor film and the second metal films 32 and 332 may be reversed. That is, in the first TFTs 15 and 315, the gate insulating films 33, 133, and 333 may be located on the upper layer sides of the first gate electrodes 15A, 215A, and 315E and the third gate electrode 315F constituted by the second metal films 32 and 332, and the first semiconductor portions 15D, 215D, 315G, and 415D constituted by a semiconductor film may be located on the upper layer sides of the gate insulating films 33, 133, and 333. In this case, the first TFTs 15 and 315 are a bottom gate type. Further, the semiconductor film may be constituted by an amorphous silicon thin film. The second TFT 24 is also a bottom gate type.

(19) The configurations of the first TFTs 15 and 315 and the second TFT 24 may be a double-gate type or the like other than a top-gate type or a bottom-gate type.

(20) An “upper electrode”, which is an electrode located on the upper layer side out of the pixel electrode 25 and the common electrode 28, may be the common electrode 28, and a “lower electrode”, which is an electrode located on the lower layer side, may be the pixel electrode 25. In this case, a slit is provided in the common electrode 28, which is the “upper electrode”.

(21) The touch panel pattern may be a mutual-capacitance type in addition to a self-capacitance type.

(22) The liquid crystal panel 11 may not have a touch panel pattern (touch panel function). In this case, the common electrode 28 has a non-divided structure, the touch electrode 29 is not formed, and the touch wiring line 30 (third metal film) is not formed.

(23) A display mode of the liquid crystal panel 11 may be a VA mode, an IPS mode, or the like other than an FFS mode.

(24) The liquid crystal panel 11 may be a reflective type or a semi-transmissive type other than a transmissive type. When the liquid crystal panel 11 is a reflective type, the backlight device can be omitted.

(25) A display panel other than the liquid crystal panel 11 (such as an organic EL display panel) may be used.

While preferred embodiments of the present invention have been described above, it is to be understood that variations and modifications will be apparent to those skilled in the art without departing from the scope and spirit of the present invention. The scope of the present invention, Thus, is to be determined solely by the following claims.

1. A transistor comprising:
a semiconductor portion extending in a first direction and made of a semiconductor material;
a first electrode disposed overlapping a portion of the semiconductor portion;
a first insulating film interposed between the first electrode and the semiconductor portion;
a second electrode disposed overlapping a portion of the semiconductor portion and connected to the semiconductor portion; and
a third electrode disposed overlapping a portion of the semiconductor portion at a position spaced apart from a connection position between the second electrode and the semiconductor portion in the first direction and connected to the semiconductor portion,
wherein the first insulating film includes a first thick portion, a second thick portion having the same film thickness as a film thickness of the first thick portion, a third thick portion having a film thickness larger than the film thickness of the first thick portion, a fourth thick portion having a film thickness larger than the film thickness of the first thick portion, and a fifth thick portion having a film thickness larger than the film thickness of the first thick portion,
the first thick portion is disposed at a position overlapping both the first electrode and the semiconductor portion,
the second thick portion overlaps both the first electrode and the semiconductor portion and is disposed at a position spaced apart from the first thick portion in the first direction,
the third thick portion overlaps both the first electrode and the semiconductor portion and is disposed to be interposed between the first thick portion and the second thick portion in the first direction,
the fourth thick portion is disposed overlapping both the semiconductor portion and one end portion of the first electrode in the first direction, and
the fifth thick portion is disposed overlapping both the semiconductor portion and the other end portion of the first electrode in the first direction.

2. The transistor according to claim 1,
wherein the first insulating film has a layered structure of a lower insulating film disposed on an upper layer side of the semiconductor portion and an upper insulating film disposed on an upper layer side of the lower insulating film and made of a material different from a material of the lower insulating film.

3. The transistor according to claim 1,
wherein the first insulating film has a single-layer structure.

4. The transistor according to claim 1,
wherein the third thick portion, the fourth thick portion, and the fifth thick portion have the same film thickness.

5. The transistor according to claim 1,
wherein the first thick portion and the second thick portion have the same dimension in the first direction.

6. The transistor according to claim 1,
wherein the second electrode is connected to a signal supply source and receives a signal supplied from the signal supply source, whereas the third electrode is connected to a signal supply target and is configured to supply the signal to the signal supply target,
the first thick portion is located closer to the second electrode in the first direction than the third thick portion, and
the second thick portion is located closer to the third electrode in the first direction than the third thick portion, and has a larger dimension in the first direction than the first thick portion.

7. The transistor according to claim 1,
wherein a polysilicon semiconductor material is used as the semiconductor material for the semiconductor portion.

8. The transistor according to claim 1,
wherein an oxide semiconductor material is used as the semiconductor material for the semiconductor portion.

9. A transistor comprising:
a semiconductor portion extending in a first direction and made of a semiconductor material;
a first electrode disposed overlapping a portion of the semiconductor portion;
a fourth electrode overlapping a portion of the semiconductor portion and disposed at a position spaced apart from the first electrode in the first direction;
a first insulating film interposed between the first and fourth electrodes and the semiconductor portion;
a second electrode disposed overlapping a portion of the semiconductor portion and connected to the semiconductor portion; and
a third electrode disposed overlapping a portion of the semiconductor portion at a position spaced apart from a connection position between the second electrode and the semiconductor portion in the first direction and connected to the semiconductor portion,
wherein the first insulating film includes a first thick portion, a second thick portion having the same film thickness as a thickness of the first thick portion, a third thick portion having a film thickness larger than the thickness of the first thick portion, a fourth thick portion having a film thickness larger than the thickness of the first thick portion, and a fifth thick portion having a film thickness larger than the thickness of the first thick portion,
the first thick portion is disposed at a position overlapping both the first electrode and the semiconductor portion,
the second thick portion is disposed at a position overlapping both the fourth electrode and the semiconductor portion,
the third thick portion is disposed to be interposed between the first thick portion and the second thick portion in the first direction,
the fourth thick portion overlaps both one end portion of the first electrode in the first direction and the semiconductor portion, and is disposed to sandwich the first thick portion with the third thick portion,
the fifth thick portion overlaps both one end portion of the fourth electrode in the first direction and the semiconductor portion, and is disposed to sandwich the second thick portion with the third thick portion, and
the third thick portion is disposed overlapping both the semiconductor portion and the other end portion of the first electrode in the first direction and overlapping both the semiconductor portion and the other end portion of the fourth electrode in the first direction.

10. A manufacturing method for a transistor, the method comprising:
forming a semiconductor film made of a semiconductor material and patterning the semiconductor film to provide a semiconductor portion extending in a first direction;
forming a first insulating film on an upper layer side of the semiconductor portion;
forming a first resist film made of a photosensitive material on an upper layer side of the first insulating film;
exposing and developing the first resist film;
etching the first insulating film using the first resist film as a mask to provide a first thick portion overlapping the semiconductor portion, a second thick portion overlapping the semiconductor portion, disposed at a position spaced apart from the first thick portion in the first direction, and having the same film thickness as a thickness of the first thick portion, a third thick portion disposed to be interposed between the first thick portion and the second thick portion in the first direction at a position overlapping the semiconductor portion and having a film thickness larger than the thickness of the first thick portion, a fourth thick portion overlapping the semiconductor portion, disposed to sandwich the first thick portion with the third thick portion in the first direction, and having a film thickness larger than the thickness of the first thick portion, and a fifth thick portion overlapping the semiconductor portion, disposed to sandwich the second thick portion with the third thick portion in the first direction, and having a film thickness larger than the thickness of the first thick portion;
forming a first conductive film on an upper layer side of the first insulating film;
forming a second resist film made of a photosensitive material on an upper layer side of the first conductive film;
exposing and developing the second resist film;
etching the first conductive film using the second resist film as a mask to provide a first electrode in which one end portion in the first direction overlaps the fourth thick portion, the other end portion in the first direction overlaps the fifth thick portion, and a portion between both end portions in the first direction overlaps the first thick portion, the second thick portion, and the third thick portion; and
forming a second conductive film on an upper layer side of the first electrode and patterning the second conductive film to provide a second electrode that is disposed overlapping a portion of the semiconductor portion and is connected to the semiconductor portion, and a third electrode that is disposed overlapping a portion of the semiconductor portion at a position spaced apart from a connection position between the second electrode and the semiconductor portion in the first direction and is connected to the semiconductor portion.

11. The manufacturing method for the transistor according to claim 10, the manufacturing method further comprising:
forming the first resist film made of a positive type photosensitive material on the upper layer side of the first insulating film;
exposing the first resist film through a first photomask and then developing the first resist film, the first photomask including a first light shielding region that is disposed overlapping formation areas for the fourth thick portion and the fifth thick portion to be formed to block light, a first transmissive region that overlaps formation areas for the first thick portion and the second thick portion to be formed to transmit light, and a semi-transmissive region that overlaps a formation area for the third thick portion to be formed, is disposed to be interposed between two of the first transmissive regions in the first direction, and has a light transmittance higher than a light transmittance of the first light shielding region and lower than a light transmittance of the first transmissive region;
forming the second resist film made of a negative photosensitive material on the upper layer side of the first conductive film; and
exposing the second resist film through the first photomask and then developing the second resist film.

12. A manufacturing method for a transistor, the manufacturing method comprising:
forming a semiconductor film made of a semiconductor material and patterning the semiconductor film to provide a semiconductor portion extending in a first direction;
forming a first insulating film on an upper layer side of the semiconductor portion;
forming a first resist film made of a photosensitive material on an upper layer side of the first insulating film;
exposing and developing the first resist film;
etching the first insulating film using the first resist film as a mask to provide a first thick portion overlapping the semiconductor portion, a second thick portion overlapping the semiconductor portion, disposed at a position spaced apart from the first thick portion in the first direction, and having the same film thickness as a thickness of the first thick portion, a third thick portion disposed to be interposed between the first thick portion and the second thick portion in the first direction at a position overlapping the semiconductor portion and having a film thickness larger than the thickness of the first thick portion, a fourth thick portion overlapping the semiconductor portion, disposed to sandwich the first thick portion with the third thick portion in the first direction, and having a film thickness larger than the thickness of the first thick portion, and a fifth thick portion overlapping the semiconductor portion, disposed to sandwich the second thick portion with the third thick portion in the first direction, and having a film thickness larger than the thickness of the first thick portion;
forming a first conductive film on an upper layer side of the first insulating film;
forming a second resist film made of a photosensitive material on an upper layer side of the first conductive film;
exposing and developing the second resist film;
etching the first conductive film using the second resist film as a mask to provide a first electrode in which one end portion in the first direction overlaps the fourth thick portion, the other end portion in the first direction overlaps the third thick portion, and a portion between both end portions in the first direction overlaps the first thick portion, and a fourth electrode in which one end portion in the first direction overlaps the fifth thick portion, the other end portion in the first direction overlaps the third thick portion, and a portion between both end portions in the first direction overlaps the second thick portion; and
forming a second conductive film on an upper layer side of the first electrode and patterning the second conductive film to provide a second electrode that is disposed overlapping a portion of the semiconductor portion and is connected to the semiconductor portion, and a third electrode that is disposed overlapping a portion of the semiconductor portion at a position spaced apart from a connection position between the second electrode and the semiconductor portion in the first direction and is connected to the semiconductor portion.

13. The manufacturing method for the transistor according to claim 12, the manufacturing method further comprising:
forming the first resist film made of a positive type photosensitive material on the upper layer side of the first insulating film;
exposing the first resist film through a second photomask and then developing the first resist film, the second photomask including a second light shielding region that is disposed overlapping formation areas for the third thick portion, the fourth thick portion, and the fifth thick portion to be formed to block light, and a second transmissive region that overlaps formation areas for the first thick portion and the second thick portion to be formed to transmit light;
forming the second resist film made of a negative photosensitive material on the upper layer side of the first conductive film; and
exposing the second resist film through the second photomask and then developing the second resist film.
